(19) United States
(12) Patent Application Publication
(10) Pub. No.: US 2026/0262517 A1
(43) Pub. Date: Sep. 3, 2026

(54) SEMICONDUCTOR PACKAGE

(71) Applicant: LG INNOTEK CO., LTD., Seoul (KR)

(72) Inventors: Dong Keon LEE, Seoul (KR); Jun Sik SHIN, Seoul (KR); Hyun Dong CHO, Seoul (KR)

(73) Assignee: LG INNOTEK CO., LTD., Seoul (KR)

(21) Appl. No.: 18/878,475

(22) PCT Filed: Jun. 27, 2023
(86) PCT No.: PCT/KR2023/008903

§ 371 Date: Dec. 23, 2024

(30) Foreign Application Priority Data
Jun. 27, 2022 (KR) 10-2022-0078536

(51) Int. Cl. H10W 70/65; H10W 42/00; H10W 70/63; H10W 70/68

(52) U.S. Cl. CPC H10W 70/65; H10W 42/121; H10W 70/635; H10W 70/682

(57) ABSTRACT

A semiconductor package according to an embodiment includes a photosensitive insulating layer; a first circuit pattern layer embedded in the photosensitive insulating layer; and a lower oxide layer disposed at an interface between the photosensitive insulating layer and the first circuit pattern layer.

### TECHNICAL FIELD

The embodiment relates to a circuit board, and more particularly to a circuit board including a cavity and a semiconductor package including the same.

### BACKGROUND ART

High performance of electric/electronic products is progressing, and accordingly, technologies are being proposed and studied to attach a greater number of packages to a substrate of limited size.

A typical semiconductor package has a structure in which a plurality of chips are disposed. In addition, a size of the semiconductor package is increasing due to high specifications of products to which the semiconductor package is applied and an adoption of a plurality of chips such as HBM (High Bandwidth Memory). Accordingly, the semiconductor package includes an interposer to connect the plurality of chips.

In addition, semiconductor packages applied to products that provide the Internet of Things (IoT), autonomous vehicles, and high-performance servers, etc. require high performance and high reliability in line with a trend toward high integration. Here, high performance may include conditions such as high-speed transmission of signals, integration of semiconductor packages, and high allowable current of transmittable signals.

At this time, the semiconductor package uses a substrate including a cavity for miniaturization and integration. Through this, the substrate is reduced in thickness, and accordingly, a thickness of the semiconductor package is reduced.

(Patent Document 1) KR 10-2021-0024840 A

### DISCLOSURE

### Technical Problem

The embodiment provides a circuit board having a novel structure and a semiconductor package including the same.

In addition, the embodiment provides a circuit board including a cavity and a semiconductor package including the same.

In addition, the embodiment provides a circuit board capable of improving circuit integration and a semiconductor package including the same.

In addition, the embodiment provides a circuit board having improved adhesion between insulating layers including different insulating materials and a semiconductor package including the same.

In addition, the embodiment provides a circuit board having improved adhesion between a plurality of adjacent layers and a semiconductor package including the same.

In addition, the embodiment provides a circuit board and a semiconductor package including the same capable of resolving a reliability problem that occurs due to exposure of glass fibers of a prepreg.

Technical problems to be solved by the proposed embodiments are not limited to the above-mentioned technical problems, and other technical problems not mentioned may be clearly understood by those skilled in the art to which the embodiments proposed from the following descriptions belong.

### Technical Problem

A semiconductor package according to an embodiment comprises a photosensitive insulating layer; a first circuit pattern layer embedded in the photosensitive insulating layer; and a lower oxide layer disposed at an interface between the photosensitive insulating layer and the first circuit pattern layer.

In addition, the lower oxide layer is further provided on a lower surface of the photosensitive insulating layer that does not vertically overlap with the first circuit pattern layer.

In addition, the semiconductor package further comprises an additional insulating layer provided on a lower surface of the photosensitive insulating layer, and wherein the lower oxide layer provided on the lower surface of the photosensitive insulating layer contacts an upper surface of the additional insulating layer.

In addition, the additional insulating layer includes an insulating material different from an insulating material of the photosensitive insulating layer.

In addition, the additional insulating layer includes a reinforcing fiber.

In addition, the additional insulating layer is a thermosetting insulating layer.

In addition, the semiconductor package further comprises a through electrode passing through the photosensitive insulating layer; and a second circuit pattern layer disposed on the photosensitive insulating layer, and wherein the lower oxide layer includes an open region vertically overlapping with a lower surface of the through electrode.

In addition, the semiconductor package further comprises an upper oxide layer disposed on the photosensitive insulating layer.

In addition, at least one of the upper oxide layer and the lower oxide layer includes an aluminum oxide.

In addition, the semiconductor package further comprises a protective layer disposed on the upper oxide layer, and wherein the upper oxide layer includes: a first portion disposed at an interface between the photosensitive insulating layer and the protective layer, and a second portion disposed at an interface between the second circuit pattern layer and the protective layer.

In addition, the protective layer includes an opening vertically overlapping with the second circuit pattern layer, and the second portion of the upper oxide layer includes an open region vertically overlapping with the opening of the protective layer.

In addition, the semiconductor package further comprises a protective layer disposed on the upper oxide layer, and the oxide layer includes a first portion disposed at an interface between the photosensitive insulating layer and the protective layer, and a second portion disposed between the photosensitive insulating layer and the second circuit pattern layer.

In addition, the upper oxide layer further includes a third portion disposed between an inner wall of a through hole passing through the photosensitive insulating layer and the through electrode.

In addition, the photosensitive insulating layer includes at least one cavity passing through an upper surface and a lower surface of the photosensitive insulating layer, and the upper oxide layer further includes a fourth portion disposed on an inner wall of the cavity of the photosensitive insulating layer.

In addition, the upper oxide layer or the lower oxide layer further comprises a fifth portion disposed on an upper surface of the additional insulating layer corresponding to a lower surface of the cavity.

In addition, the first circuit pattern layer includes a pad vertically overlapping the cavity, and the fifth portion of the upper oxide layer or the lower oxide layer includes an open region vertically overlapping an upper surface of the pad.

In addition, the first circuit pattern layer includes a circuit pattern that is not vertically overlapped with the cavity and is covered with the photosensitive insulating layer; and a trace that directly connects the circuit pattern and the pad, and the trace includes a first part in direct contact with the pad and vertically overlapping the cavity, and a second part covered with the photosensitive insulating layer and in direct contact with the circuit pattern, and the upper oxide layer or the lower oxide layer further includes a sixth portion disposed on an upper surface and a side surface of the second part of the trace.

In addition, the semiconductor package further comprises a connection member disposed on the pad.

In addition, the semiconductor package further comprises a semiconductor device disposed on the connection member.

In addition, the semiconductor package further comprises a molding layer disposed in the cavity and molding the semiconductor device.

In addition, the upper oxide layer includes a portion disposed on the inner wall of the cavity and in contact with the molding layer.

### Advantageous Effects

The circuit board of the embodiment can improve an adhesion between a plurality of layers.

Specifically, the circuit board of the embodiment comprises a first insulating layer including a first insulating material, and a second insulating layer disposed on the first insulating layer and including a second insulating material different from the first insulating material.

At this time, the embodiment includes a buffer layer disposed between the first insulating layer and the second insulating layer. The buffer layer can function as an adhesive layer that improves the adhesion between the first insulating layer and the second insulating layer. The buffer layer can be an oxide layer. For example, the buffer layer can include aluminum oxide.

Through this, the embodiment can improve the adhesion between the first insulating layer and the second insulating layer, thereby improving the physical reliability and/or electrical reliability of the circuit board and the semiconductor package including the same.

Furthermore, the first insulating layer can include a thermosetting resin, and the second insulating layer can include a photocurable resin. The embodiment can improve the physical and electrical reliability of the circuit pattern layer and the through electrode disposed on the second insulating layer by the second insulating layer including the photocurable resin. Furthermore, the circuit pattern layer and the through electrode disposed on the second insulating layer can be miniaturized by the second insulating layer including the photocurable resin.

At this time, the photocurable resin has a relatively high ceramic particle content and a relatively high curing shrinkage rate. Accordingly, there may be a problem that the adhesion between the photocurable resin and other layers is reduced.

In contrast, the embodiment includes a buffer layer disposed on a surface of the photocurable resin. Accordingly, the embodiment can miniaturize the circuit pattern layer and the through electrode without affecting the adhesion even if the second insulating layer includes the photocurable resin.

Therefore, the embodiment can improve a circuit integration of the circuit board, and further improve the physical and/or electrical reliability of the circuit board.

Meanwhile, the buffer layer of the embodiment is also disposed between the second insulating layer and the circuit pattern layer. Accordingly, the embodiment can improve the adhesion between the second insulating layer and the circuit pattern layer.

In addition, the buffer layer of the embodiment is also disposed between the second insulating layer and the through electrode. Accordingly, the embodiment can improve the adhesion between the second insulating layer and the through electrode.

In addition, the buffer layer of the embodiment is also disposed between the second insulating layer and a first protective layer. Accordingly, the embodiment can improve the adhesion between the second insulating layer and the first protective layer.

In addition, the buffer layer of the embodiment is also disposed between the circuit pattern layer and the first protective layer. Accordingly, the embodiment can improve the adhesion between the circuit pattern layer and the first protective layer.

The embodiment can improve the adhesion between a plurality of layers constituting the circuit board by forming a buffer layer having a structure as described above, and can improve product reliability accordingly.

Meanwhile, the second insulating layer includes a cavity. At this time, the buffer layer can also be disposed on an inner wall of the cavity of the second insulating layer. Accordingly, the embodiment can omit a de-smear process for removing debris remaining on the inner wall of the cavity. Accordingly, the embodiment can simplify a manufacturing process of the circuit board. Furthermore, the embodiment can prevent a size of the cavity from being expanded by the de-smear process by omitting the de-smear process, thereby forming a cavity having an optimal size. Accordingly, the embodiment can reduce a volume of the circuit board.

In addition, the buffer layer can also be disposed on a lower surface of the cavity. In addition, if the de-smear process is performed after forming the cavity, the buffer layer disposed on a lower surface of the cavity can function as a barrier layer. In addition, the embodiment can prevent a reinforcing fiber included in the first insulating layer from being exposed by the barrier layer in the de-smear process. Accordingly, the embodiment can further improve product reliability.

### DESCRIPTION OF DRAWINGS

FIG. 1a is a view showing a semiconductor package according to a first embodiment.

FIG. 1b is a view showing a semiconductor package according to a second embodiment.

FIG. 1c is a view showing a semiconductor package according to a third embodiment.

FIG. 1d is a view showing a semiconductor package according to a fourth embodiment.

FIG. 1e is a view showing a semiconductor package according to a fifth embodiment.

FIG. 1f is a view showing a semiconductor package according to a sixth embodiment.

FIG. 2 is a cross-sectional view showing a circuit board according to a first embodiment.

FIG. 3 is a cross-sectional view explaining an arrangement structure of a first buffer layer according to one embodiment.

FIG. 4 is a cross-sectional view explaining an arrangement structure of a second buffer layer according to a first embodiment.

FIG. 5 is a cross-sectional view explaining an arrangement structure of a second buffer layer according to a second embodiment.

FIG. 6 is a drawing showing a circuit board according to a second embodiment.

FIG. 7a is a cross-sectional view showing a circuit board according to a third embodiment.

FIG. 7b is a plan view of the circuit board of FIG. 7a.

FIG. 8 is a drawing showing a semiconductor package of a seventh embodiment.

FIG. 9 is a drawing showing a semiconductor package of an eighth embodiment.

FIGS. 10 to 17 are cross-sectional views for explaining a method of manufacturing a circuit board of the embodiment in order of processes.

### MODE FOR INVENTION

Hereinafter, embodiments of the present disclosure will be described in detail with reference to the accompanying drawings.

However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present disclosure, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements. Further, when expressed as “on (over)” or “under (below)”, it may include not only the upper direction but also the lower direction based on one element.

### Electronic Device

Before describing an embodiment, an electronic device to which a semiconductor package of the embodiment is applied will be briefly described. The electronic device includes a main board (not shown). The main board may be physically and/or electrically connected to various components. For example, the main board may be connected with the semiconductor package of the embodiment. In addition, various semiconductor devices can be mounted in the semiconductor package.

The semiconductor device may include an active device and/or a passive device, and have various functions. The active device may be a semiconductor device in the form of an integrated circuit (IC) in which hundreds to millions of devices are integrated into a single chip. The semiconductor device may be a logic chip, a memory chip, or the like. The logic chip may be a central processor (CPU), a graphic processor (GPU), or the like. For example, the logic chip may be an application processor (AP) semiconductor device including at least one of a central processor (CPU), a graphic processor (GPU), a digital signal processor, a cryptographic processor, a microprocessor, and a microcontroller, or an analog-to-digital converter, an application-specific IC (ASIC), etc., or a chip set that includes a specific combination of those listed so far.

The memory chip may be a stack memory such as HBM. Also, the memory chip may include a memory chip such as a volatile memory (eg, DRAM), a non-volatile memory (eg, ROM), or a flash memory.

A product group to which the semiconductor package of the embodiment is applied include CSP (Chip Scale Package), FC-CSP (Flip Chip-Chip Scale Package), FC-BGA (Flip Chip Ball Grid Array), POP (Package On Package), and SIP (System In Package) , but is not limited thereto.

In addition, the electronic device may include a smart phone, a personal digital assistant, a digital video camera, a digital still camera, a network system, a computer, a monitor, a tablet, a laptop, a netbook, a television, a video game, a smart watch, an automotive, and the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later.

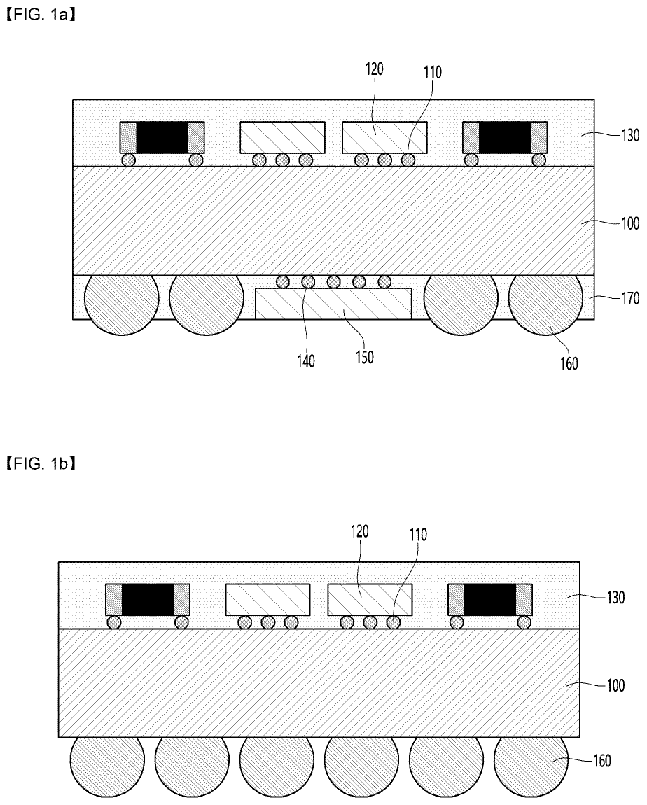

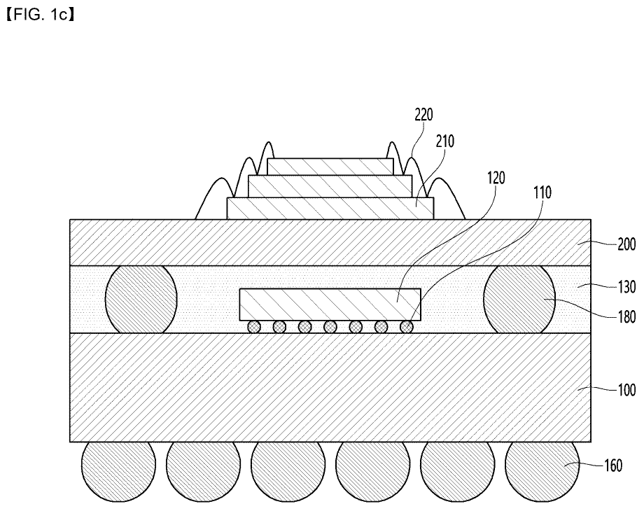

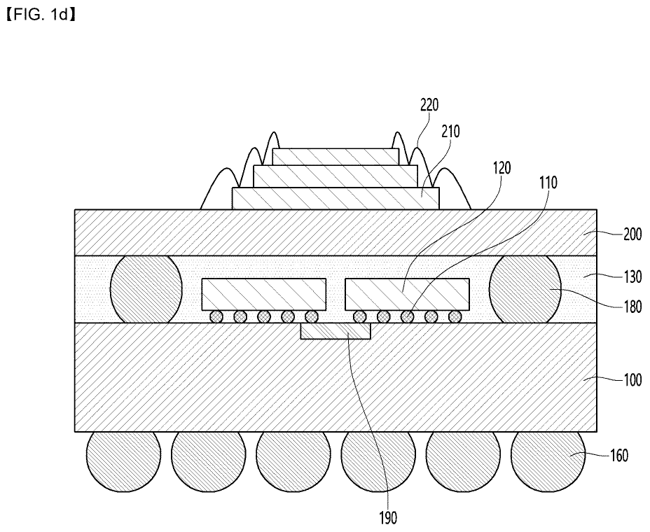

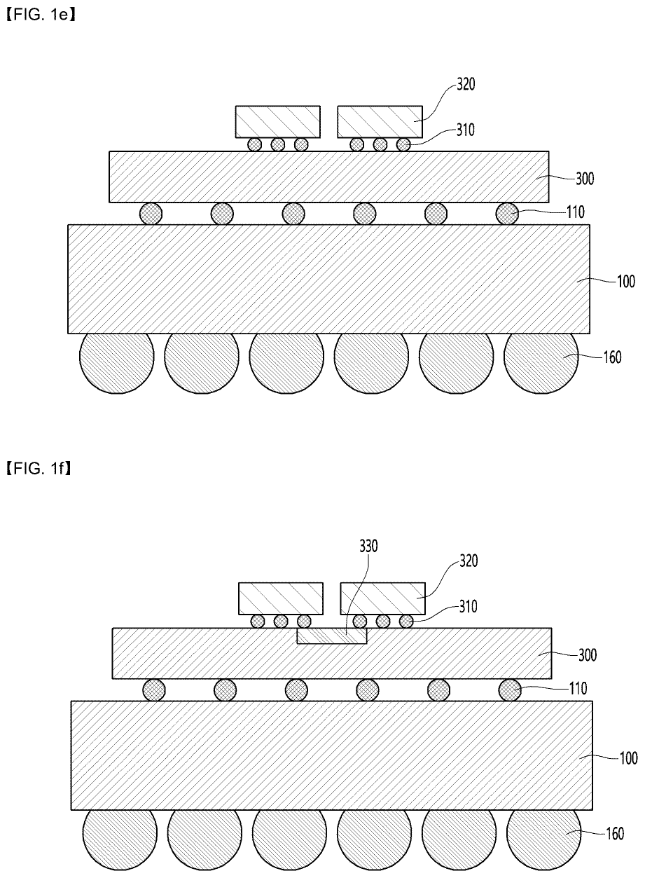

FIG. 1a is a view showing a semiconductor package according to a first embodiment.

Referring to FIG. 1a, a semiconductor package of a first embodiment includes a first substrate 100.

The first substrate 100 may mean a package substrate.

For example, the first substrate 100 may provide a space to which at least one external substrate is coupled. For example, the first substrate 100 may provide a space to which a main board included in an electronic device is coupled.

As described below, the first substrate 100 may include at least one insulating layer, a circuit pattern layer disposed on the at least one insulating layer, a through electrode penetrating the at least one insulating layer, and a protective layer protecting the insulating layer and the circuit pattern layer.

The first substrate 100 may include a plurality of pads. Here, the plurality of pads may mean a part of the circuit pattern layer disposed on an outermost layer of the first substrate 100. For example, the pad may mean a part of the circuit pattern layer disposed on an uppermost side of the first substrate 100. For example, the pad may mean a part of the circuit pattern layer disposed on a lowermost side of the first substrate 100. In addition, the protective layer may include an opening that exposes a surface (e.g., an upper surface or a lower surface) of the pad.

Meanwhile, the semiconductor package may include a plurality of connection members.

For example, the first substrate 100 may include a plurality of pads, and the plurality of connection members may be respectively disposed on the plurality of pads.

Specifically, the first substrate 100 may include a plurality of first pads. In addition, the semiconductor package may include a first connection member 110 disposed on the plurality of first pads.

In addition, the first substrate 100 may include a plurality of second pads. In addition, the semiconductor package may include a second connection member 140 disposed on the plurality of second pads.

In addition, the first substrate 100 may include a plurality of third pads. In addition, the semiconductor package may include a third connection member 160 disposed on the plurality of third pads.

At this time, the first pad may be disposed on an upper surface of the first substrate 100. In addition, the second and third pads may be disposed on a lower surface of the first substrate 100.

Meanwhile, the semiconductor package may include a plurality of semiconductor devices.

For example, the semiconductor package may include a first semiconductor device 120 disposed on the first connection member 110. At this time, the first pads of the first substrate 100 may be divided into a plurality of groups. In addition, the first connection member 110 may be disposed on each of the first pads of the plurality of groups. In addition, the first semiconductor device 120 may be mounted on each of the first pads of the plurality of groups. Accordingly, the first semiconductor device 120 may be mounted on an upper side of the first substrate 100 at a predetermined spacing from each other. At this time, the first semiconductor device 120 may refer to a semiconductor device mounted on an upper side of the first substrate 100. In addition, a plurality of first semiconductor devices may be disposed on the upper side of the first substrate 100 at a predetermined spacing from each other.

In addition, the semiconductor package may include a second semiconductor device 140 disposed under the second connection member 140. The second semiconductor device 140 may refer to a semiconductor device mounted on a lower side of the first substrate 100 among the semiconductor devices included in the semiconductor package. In addition, a plurality of second semiconductor devices may be disposed on the lower side of the first substrate 100 at a predetermined spacing from each other.

In this time, at least one of the first semiconductor device 120 and the second semiconductor device 140 may include a logic chip. For example, at least one of the first semiconductor device 120 and the second semiconductor device 140 may include an application processor chip. For example, at least one of the first semiconductor device 120 and the second semiconductor device 140 may include an analog-to-digital converter or an ASIC (application-specific IC). For example, at least one of the first semiconductor device 120 and the second semiconductor device 140 may include a memory chip. The memory chip may be a stack memory such as HBM. For example, the memory chip may include a volatile memory (e.g., DRAM), a non-volatile memory (e.g., ROM), a flash memory, etc.

In addition, at least one of the first semiconductor device 120 and the second semiconductor device 140 may include at least one of a drive IC chip, a diode chip, a power IC chip, a touch sensor IC chip, an MLCC (Multi layer ceramic condenser) chip, a BGA (Ball Grid Array) chip, and a chip condenser.

In addition, the semiconductor package may include a third connection member 160. The third connection member 160 may be positioned under the third pad of the first substrate 100. The third connection member 160 may connect between the first substrate 100 and a main board of an electronic device. The third connection member 160 may have a larger diameter than the first connection member 110 and the second connection member 140. For example, a diameter of the third connection member 160 may satisfy a range of 10 to 200 times a diameter of at least one of the first connection member 110 and the second connection member 140. For example, the diameter of the third connection member 160 may satisfy a range of 20 to 180 times the diameter of at least one of the first connection member 110 and the second connection member 140. For example, the diameter of the third connection member 160 may satisfy a range of 40 to 150 times the diameter of at least one of the first connection member 110 and the second connection member 140. That is, the third connection member 160 is connected to the main board of the electronic device and may have a larger diameter than the other connection members to correspond to a width of a pad part of the main board. In addition, the first connection member 110 and the second connection member 140 are connected to the semiconductor device and may have a smaller diameter than the third connection member 160 to correspond to a terminal of the semiconductor device.

The semiconductor package may include a molding layer.

For example, the semiconductor package may include a first molding layer 130 disposed on the first substrate 100. The first molding layer 130 may mold components disposed on an outermost layer of the first substrate 100. For example, the first molding layer 130 can mold a surface of the protective layer, a surface of the circuit pattern layer, and a surface of the insulating layer disposed on an uppermost side of the first substrate 100. In addition, the first molding layer 130 can mold the first connection member 110 and the first semiconductor device 120 disposed on the first substrate 100. At this time, the semiconductor package can further include an underfill (not shown) surrounding the first connection member 110 and the first semiconductor device 120. In addition, when the semiconductor package includes the underfill, the first molding layer 130 can mold a periphery of the underfill.

In addition, the semiconductor package may include a second molding layer 170 disposed under the first substrate 100. The second molding layer 170 may mold a surface of the protective layer, a surface of the circuit pattern layer, and a surface of the insulating layer disposed on a lowermost side of the first substrate 100. In addition, the second molding layer 170 may mold the second connection member 140 and the second semiconductor device 140 disposed under the first substrate 100. In addition, the second molding layer 170 may mold the third connection member 160.

At this time, the second molding layer 170 may expose at least a portion of a lower surface of the second semiconductor device 140. For example, a lower surface of the second molding layer 170 may be positioned not lower than a lower surface of the second semiconductor device 140. For example, the lower surface of the second molding layer 170 may be positioned on a same plane as the lower surface of the second semiconductor device 140.

In addition, the second molding layer 170 may be positioned not lower than the lower surface of the third connection member 160. For example, the lower surface of the second molding layer 170 may be positioned on a same plane as the lower surface of the third connection member 160 or higher than the lower surface of the third connection member 160. Therefore, the lower surface of the third connection member 160 may not be covered by the second molding layer 170. In addition, at least a portion of the third connection member 160 may protrude downward from the second molding layer 170.

The first molding layer 130 and the second molding layer 170 may be an EMC (Epoxy Mold Compound), but are not limited thereto. The first molding layer 130 and the second molding layer 170 may have a low permittivity. For example, the permittivity (Dk) of the first molding layer 130 and the second molding layer 170 may be 0.2 to 10. For example, the permittivity (Dk) of the first molding layer 130 and the second molding layer 170 may be 0.5 to 8. For example, the permittivity (Dk) of the first molding layer 130 and the second molding layer 170 may be 0.8 to 5. Accordingly, in the embodiment, the heat dissipation characteristics of heat generated from the first semiconductor device 120 and the second semiconductor device 140 may be improved by making the first molding layer 130 and the second molding layer 170 have low permittivity. The semiconductor package of the first embodiment may have a double-sided molding structure as described above.

That is, the semiconductor package of the first embodiment may have a structure in which at least one first semiconductor device 120 and a second semiconductor device 140 are mounted on the upper and lower sides of the first substrate 100, respectively.

FIG. 1b is a view showing a semiconductor package according to a second embodiment.

Referring to FIG. 1b, the semiconductor package according to the second embodiment may differ from the semiconductor package of the first embodiment of FIG. 1a in that the semiconductor package has a one-sided molding structure.

For example, the semiconductor package of the second embodiment may include a first substrate 100, a first connection member 110, a first semiconductor device 120, a first molding layer 130, and a third connection member 160.

In addition, the semiconductor package of the second embodiment may have a structure in which the semiconductor device is mounted only on the upper side of the first substrate 100. Accordingly, the molding layer of the semiconductor package of the second embodiment may be disposed only on the upper side of the first substrate 100.

FIG. 1c is a view showing a semiconductor package according to a third embodiment.

Referring to FIG. 1c, the semiconductor package according to the third embodiment is different from the semiconductor package of the second embodiment of FIG. 1b in that the semiconductor package further includes an additional package.

The semiconductor package of the third embodiment may further include a fourth pad disposed on an upper side of the first substrate 100. That is, a circuit pattern layer is disposed on an upper surface of the first substrate 100. In addition, a part of the circuit pattern layer may function as a first pad on which the first semiconductor device 120 is mounted, and another part may function as a fourth pad.

The semiconductor package of the third embodiment may further include a fourth connection member 180 disposed on the fourth pad.

An upper surface of the fourth connection member 180 may not be covered with the first molding layer 130.

The semiconductor package of the third embodiment may include a second substrate 200 disposed on the fourth connection member 180. The second substrate 200 may be a memory substrate, but is not limited thereto.

The semiconductor package of the third embodiment may include a third semiconductor device 210 mounted on the second substrate 200. The third semiconductor device 210 may be a memory chip, but is not limited thereto.

In addition, the semiconductor package of the third embodiment may further include a connecting member 220 connecting the second substrate 200 and the third semiconductor device 210. That is, the semiconductor package of the third embodiment of FIG. 1c may have a package-on-package structure.

FIG. 1d is a view showing a semiconductor package according to a fourth embodiment.

Referring to FIG. 1d, the semiconductor package according to the fourth embodiment is different from the semiconductor package of the third embodiment of FIG. 1c in that the first semiconductor device 120 includes a plurality of logic chips and an additional third substrate 190 is disposed on the first substrate 100.

For example, a plurality of logic chips may be disposed on the first substrate 100. For example, a plurality of logic chips of the same type may be disposed on the first substrate 100, or, differently, a plurality of logic chips of different types may be disposed.

At this time, a connecting member may be disposed on the first substrate 100 to connect the plurality of first semiconductor devices 120. The connecting member may mean a third substrate 190.

The third substrate 190 may be a bridge substrate. The third substrate 190 may include a redistribution layer. The third substrate 190 is disposed on the first substrate 100. In addition, the third substrate 190 can electrically connect a plurality of first semiconductor devices 120 corresponding to a plurality of logic chips. At this time, although the drawing illustrates that the third substrate 190 is embedded in the first substrate 100, the embodiment is not limited thereto. For example, the third substrate 190 may be disposed on the first substrate 100.

The third substrate 190 may be a silicon bridge substrate. Alternatively, the third substrate 190 may be an organic bridge including an organic material.

FIG. 1e is a view showing a semiconductor package according to a fifth embodiment.

Referring to FIG. 1e, the semiconductor package according to the fifth embodiment is different from the semiconductor package of the previous embodiment in that a fourth substrate 300 is disposed between the first substrate and the first semiconductor device.

The semiconductor package according to the fifth embodiment may include a fourth substrate 300 disposed on the first substrate 100.

To this end, a first connection member 110 connecting the first substrate 100 and the fourth substrate 300 may be disposed on the first substrate 100.

In addition, the semiconductor package according to the fifth embodiment may include a fifth connection member 320 disposed on the fourth substrate 300. In addition, the semiconductor package according to the fifth embodiment may include a semiconductor device 320 disposed on the fifth connection member 320. The semiconductor device 320 may be provided as one, or the semiconductor device 320 may be provided in plural.

Meanwhile, the fourth substrate 300 may be disposed between the first substrate 100 and the semiconductor device 320. The fourth substrate 300 may perform a function of connecting the first substrate 100 and the semiconductor device 320. In addition, the fourth substrate 300 may perform a function of connecting a plurality of semiconductor devices 320.

At this time, the fourth substrate 300 may also be referred to as an interposer connecting the first substrate 100 and the semiconductor device 320.

In one embodiment, the fourth substrate 300 may be an active interposer that functions as a semiconductor device. When the fourth substrate 300 functions as a semiconductor device, a package of the fifth embodiment can have a structure in which a plurality of logic chips having a vertically stacked structure are mounted on the first substrate 100. In addition, a first logic chip corresponding to the active interposer among the logic chips can perform a function of the corresponding logic chip while performing a signal transmission function between a second logic chip disposed on an upper side thereof and the first substrate 100.

According to another embodiment, the fourth substrate 300 may be a passive interposer. For example, the fourth substrate 300 may perform a signal relay function between the semiconductor device 320 and the first substrate 100. For example, a number of terminals in the semiconductor device 320 is gradually increasing due to reasons such as 5G, the Internet of Things (IOT), increased image quality, and increased communication speed. That is, a number of terminals provided in the semiconductor device 320 is increasing, and thus a width of the terminal or a spacing between the plurality of terminals is decreasing. At this time, the first substrate 100 is connected to the main board of the electronic device. Accordingly, in order for the pads provided on the first substrate 100 to have a width and spacing for being connected to the semiconductor device 320 and the main board, respectively, there is a problem that a thickness of the first substrate 100 increases or a layer structure of the first substrate 100 becomes complicated. Therefore, the fourth substrate 300 may be disposed between the first substrate 100 and the semiconductor device 320. The fourth substrate 300 may include pads having a micro width and spacing corresponding to the terminals of the semiconductor device 320.

FIG. 1f is a view showing a semiconductor package according to a sixth embodiment.

Referring to FIG. 1f, the semiconductor package according to the sixth embodiment is different from the semiconductor package of the fifth embodiment in that a fifth substrate 330 is additionally disposed on the fourth substrate 300.

A plurality of semiconductor devices 320 that are horizontally spaced from each other may be disposed on the fourth substrate 300. In addition, the plurality of semiconductor devices 320 may be different types or a same type of active devices. For example, a plurality of semiconductor devices 320 may mean different types of AP chips. In addition, one of the plurality of semiconductor devices 320 may be an AP chip, and another chip may be a memory chip.

In addition, the semiconductor package of the sixth embodiment further includes a fifth substrate 330. The fifth substrate 330 may be embedded in the fourth substrate 300, but is not limited thereto. For example, the fifth substrate 330 may be disposed on the fourth substrate 300 and may perform a function of connecting the plurality of semiconductor devices 320.

The fifth substrate 330 may include a redistribution layer. For example, the fifth substrate 330 may be a bridge. The fifth substrate 330 may include a silicon bridge. Differently, the fifth substrate 330 may be an organic bridge including an organic material.

Meanwhile, each of the semiconductor packages of the first to sixth embodiments includes a connection member as described above.

At this time, the connection member may be a member that functions to electrically connect a plurality of components using at least one bonding method among wire bonding, solder bonding, and direct metal bonding.

That is, since the connection member has a function to electrically connect a plurality of components, when direct metal bonding is used, the connection member may be understood as a part that is electrically connected, not a solder or a wire.

The wire bonding method may mean electrically connecting a plurality of components using a conductor such as gold (Au). In addition, the solder bonding method may electrically connect a plurality of components using a material including at least one of Sn, Ag, and Cu. In addition, the direct metal bonding method may mean directly bonding a plurality of components by applying heat and pressure between the plurality of components without a member such as solder, wire, or conductive adhesive to recrystallize the plurality of components. In addition, the direct bonding method between metals may mean a connection member connecting a substrate and a semiconductor device. At this time, the connection member of the direct bonding method may mean a metal layer formed between a plurality of components by the recrystallization.

In addition, a cavity may be provided in at least one of the plurality of substrates included in the semiconductor package illustrated in FIGS. 1a to 1f.

The cavity may be used for different purposes depending on a function of the substrate.

For example, the cavity may be used for a purpose of arranging a semiconductor device.

For example, if a cavity is provided in the first substrate 100, the cavity may be used for a purpose of embedding at least one semiconductor device among a plurality of semiconductor devices 120 and 140.

Unlike this, if a cavity is provided in the second substrate 200, the cavity may be used for a purpose of arranging a semiconductor device 210. In addition, if a cavity is provided in the second substrate 200, the cavity may be used for a purpose of accommodating at least a part of the semiconductor device 120 disposed on the first substrate 100. Here, the semiconductor device 210 being disposed may mean that the semiconductor device 210 is electrically connected to the corresponding substrate in the cavity. In addition, the semiconductor device 120 being accommodated may mean that the semiconductor device 120 is not electrically connected to a substrate within the cavity, and at least a part of the semiconductor device 120 is positioned in a floating state within the cavity.

In addition, the cavity may be used for the purpose of arranging a bridge substrate.

For example, if a cavity is provided in the first substrate 100, the cavity may be used for a purpose of arranging a third substrate 190 connecting between a plurality of semiconductor devices.

For example, if a cavity is provided in the fourth substrate 300, the cavity may be used for a purpose of arranging a fifth substrate 330 connecting between a plurality of semiconductor devices.

The following describes a circuit board of an embodiment.

Before describing the circuit board of the embodiment, the circuit board described below may mean any one of a plurality of substrates included in a previous semiconductor package.

Preferably, a circuit board of one embodiment described below may be any one of the first substrate 100, the second substrate 200, the third substrate 190, the fourth substrate 300, and the fifth substrate 330 included in the semiconductor package. Here, the circuit board of one embodiment may mean an embodiment that does not include a cavity.

As another example, the circuit board of another embodiment described below may be any one of the first substrate 100, the second substrate 200, and the fourth substrate 300 included in the semiconductor package. Here, the circuit board of another embodiment may mean an embodiment that includes a cavity. In addition, a semiconductor device may be mounted or accommodated in the cavity, or a bridge substrate may be coupled in the cavity

FIG. 2 is a cross-sectional view showing a circuit board according to a first embodiment.

Referring to FIG. 2, the circuit board 400 includes an insulating layer 410.

The insulating layer 410 may include a plurality of layers. Preferably, the insulating layer 410 may have a multilayer structure.

The insulating layer 410 may include a first insulating layer 411, a second insulating layer 412, and a third insulating layer 413.

The first insulating layer 411 may mean an insulating layer disposed at a center in a layer structure in a vertical direction of the circuit board 400, but is not limited thereto.

The first insulating layer 411 includes a first insulating material. For example, the first insulating layer 411 may include a prepreg in which a reinforcing fiber is impregnated into a resin.

For example, a prepreg of the first insulating layer 411 may include an epoxy resin impregnated into a fiber layer in the form of a fabric sheet, such as a glass fabric woven with glass yarn.

At this time, although the first insulating layer 411 including the first insulating material is illustrated as having a single-layer structure in the drawing, it is not limited thereto. For example, the first insulating layer 411 may have a multi-layer structure of two or more layers.

The second insulating layer 412 is disposed on the first insulating layer 411. In addition, the third insulating layer 413 is disposed under the first insulating layer 411.

The second insulating layer 412 includes a second insulating material different from the first insulating material of the first insulating layer 411. Preferably, the second insulating layer 412 may not include a reinforcing fiber provided in the first insulating layer 411.

For example, the second insulating layer 412 may include at least one of ABF (Ajinomoto Build-up Film), FR-4, BT (Bismaleimide Triazine), PID (Photo Imageable Dielectric resin), BT, and RCC (Resin coated copper).

The third insulating layer 413 is disposed under the first insulating layer 411. The third insulating layer 413 may include a second insulating material that is the same as the second insulating layer 412. For example, the third insulating layer 413 may not include a reinforcing fiber. For example, the third insulating layer 413 may include at least one of ABF (Ajinomoto Build-up Film), FR-4, BT (Bismaleimide Triazine), PID (Photo Imageable Dielectric resin), BT, and RCC (Resin coated copper).

Meanwhile, although the second insulating layer 412 and the third insulating layer 413 are illustrated in the drawing as having a single-layer structure, they are not limited thereto. For example, at least one of the second insulating layer 412 and the third insulating layer 413 may have a multilayer structure of two or more layers.

The second insulating layer 412 and the third insulating layer 413 may have a thickness in a range of 10 um to 60 um. The second insulating layer 412 and the third insulating layer 413 may satisfy a thickness in a range of 15 um to 55 um. More preferably, the second insulating layer 412 and the third insulating layer 413 may satisfy a thickness in the range of 18 um to 52 um.

A thickness of each of the second insulating layer 412 and the third insulating layer 413 may mean a vertical distance between a plurality of circuit pattern layers disposed vertically adjacent to each other.

If the thickness of the second insulating layer 412 and the third insulating layer 413 is less than 10 um, warpage characteristics of the circuit board 400 may deteriorate. For example, if the thickness of the second insulating layer 412 and the third insulating layer 413 is less than 10 um, the circuit pattern layer disposed on the surface of the second insulating layer 412 and the third insulating layer 413 may not be stably protected, and thus, electrical reliability and/or physical reliability problems may occur. In addition, if the thickness of the second insulating layer 412 and the third insulating layer 413 is less than 10 um, processability in a process of forming the circuit pattern layer on the second insulating layer 412 and the third insulating layer 413 may deteriorate.

In addition, if the thickness of the second insulating layer 412 and the third insulating layer 413 exceeds 60 um, the overall thickness of the circuit board 400 may increase, and thus the thickness of the semiconductor package may increase. In addition, if the thickness of the second insulating layer 412 and the third insulating layer 413 exceeds 60 um, it may be difficult to miniaturize the circuit pattern layer. For example, if the thickness of the second insulating layer 412 and the third insulating layer 413 exceeds 60 um, it may be difficult to form a width of the circuit pattern layer and a spacing between adjacent patterns to 12 um or less, 10 um or less, 8 um or less, or 6 um or less. In addition, if the miniaturization of the circuit pattern layer is difficult, the circuit integration may decrease, and accordingly, a signal transmission distance may increase, which may increase the signal transmission loss.

The circuit board 400 includes a circuit pattern layer disposed on the insulating layer 410.

For example, the circuit board 400 may include a first circuit pattern layer 421 disposed on a first insulating layer 411. In addition, the circuit board 400 may include a second circuit pattern layer 422 disposed on an upper surface of a second insulating layer 412. In addition, the circuit board 400 may include a third circuit pattern layer 423 disposed on a lower surface of the first insulating layer 411. In addition, the circuit board 400 may include a fourth circuit pattern layer 424 disposed on a lower surface of the third insulating layer 413.

Each of the first circuit pattern layer 421, the second circuit pattern layer 422, the third circuit pattern layer 423, and the fourth circuit pattern layer 424 may include a plurality of metal layers.

For example, the first circuit pattern layer 421 may include a plurality of metal layers. For example, the first circuit pattern layer 421 may include a first metal layer disposed on an upper surface of the first insulating layer 411 and a second metal layer disposed on the first metal layer. The first metal layer of the first circuit pattern layer 421 may be a seed layer for electroplating the second metal layer of the first circuit pattern layer 421. A thickness of the first metal layer of the first circuit pattern layer 421 may satisfy a range of 0.2 um to 3.0 um. Preferably, a thickness of the first metal layer of the first circuit pattern layer 421 may satisfy a range of 0.3 um to 2.8 um. More preferably, the thickness of the first metal layer of the first circuit pattern layer 421 may satisfy a range of 0.5 um to 2.5 um.

If the thickness of the first metal layer of the first circuit pattern layer 421 is less than 0.2 um, the first metal layer of the first circuit pattern layer 421 may not function as a seed layer. If the thickness of the first metal layer of the first circuit pattern layer 421 is less than 0.2 um, it may be difficult to form a first metal layer with a uniform thickness on the upper surface of the first insulating layer 411. In addition, if the thickness of the first metal layer of the first circuit pattern layer 421 exceeds 3.0 um, a process time for forming the first metal layer of the first circuit pattern layer 421 may increase, and thus the yield may decrease. In addition, if the thickness of the first metal layer of the first circuit pattern layer 421 exceeds 3.0 um, an etching time of the first metal layer in the forming process of the first circuit pattern layer 421 may increase. In addition, if the thickness of the first metal layer of the first circuit pattern layer 421 exceeds 3.0 um, deformation of the second metal layer of the first circuit pattern layer 421 may occur when the first metal layer of the first circuit pattern layer 421 is etched. Here, deformation of the second metal layer of the first circuit pattern layer 421 may mean that a difference between a width of the upper surface and a width of the lower surface of the second metal layer increases as a side of the second metal layer is also etched when the first metal layer is etched. For example, deformation of the second metal layer of the first circuit pattern layer 421 may mean that a shape of a vertical cross-section of the second metal layer changes from a square to a trapezoidal shape.

In addition, if the thickness of the first metal layer of the first circuit pattern layer 421 exceeds 3.0 um, an etching amount in an etching process of the first metal layer increases, and accordingly, a depth of a dent (e.g., undercut) formed on the side of the first metal layer and the side of the second metal layer may increase. For example, if the etching amount in the etching process of the first metal layer increases, a difference between a width of the first metal layer and a width of the second metal layer may increase. In addition, if the difference between the width of the first metal layer and the width of the second metal layer increases, the electrical characteristics may deteriorate due to an increase in signal transmission loss. In addition, if the difference between the width of the first metal layer and the width of the second metal layer increases, dendrites may be formed by electromigration, and thereby the electrical characteristics and/or physical characteristics of the first circuit pattern layer 420 may deteriorate.

The second metal layer of the first circuit pattern layer 421 may be an electroplated layer in which the first metal layer is electroplated as a seed layer. The second metal layer of the first circuit pattern layer 421 may be formed on the first metal layer with a predetermined thickness. The second metal layer of the first circuit pattern layer 421 may include a same metal as the first metal layer of the first circuit pattern layer 421, but is not limited thereto. For example, the first metal layer and the second metal layer of the first circuit pattern layer 421 may each include copper.

A thickness of the second metal layer of the first circuit pattern layer 421 may be greater than the thickness of the first metal layer of the first circuit pattern layer 421.

The thickness of the second metal layer of the first circuit pattern layer 421 may satisfy a range of 3.5 μm to 25 μm. Preferably, the thickness of the second metal layer of the first circuit pattern layer 421 can satisfy a range of 4.0 μm to 23 μm. More preferably, the thickness of the second metal layer of the first circuit pattern layer 421 can satisfy a range of 4.5 μm to 22 μm.

If the thickness of the second metal layer of the first circuit pattern layer 421 is less than 3.5 μm, an etching of the second metal layer may also be performed during the etching process of the first metal layer. If the thickness of the second metal layer of the first circuit pattern layer 421 is less than 3.5 μm, an allowable current of a signal transmitted through the first circuit pattern layer may decrease, and thus the electrical characteristics may deteriorate. If the thickness of the second metal layer of the first circuit pattern layer 421 exceeds 25 μm, it may be difficult to miniaturize the first circuit pattern layer 421. For example, if the thickness of the second metal layer of the first circuit pattern layer 421 exceeds 25 μm, the width and spacing of the patterns constituting the first circuit pattern layer 421 may not satisfy required conditions. As a result, the circuit integration may decrease, or the volume of the circuit board and the semiconductor package may increase.

In addition, each of the second circuit pattern layer 422, the third circuit pattern layer 423, and the fourth circuit pattern layer 424 may include a first metal layer and a second metal layer corresponding to the first circuit pattern layer 421.

Meanwhile, each of the first circuit pattern layer 421, the second circuit pattern layer 422, the third circuit pattern layer 423, and the fourth circuit pattern layer 424 is said to include the first and second metal layers, but is not limited thereto. For example, each of the first circuit pattern layer 421 and the third circuit pattern layer 423 may further include a third metal layer disposed between the insulating layer and the first metal layer. In addition, the third metal layer may mean a copper layer, but is not limited thereto.

The first circuit pattern layer 421, the second circuit pattern layer 422, the third circuit pattern layer 423, and the fourth circuit pattern layer 424 may include a conductive material. For example, the first circuit pattern layer 421, the second circuit pattern layer 422, the third circuit pattern layer 423, and the fourth circuit pattern layer 424 may include at least one metal material selected from gold (Au), silver (Ag), platinum (Pt), titanium (Ti), tin (Sn), copper (Cu), and zinc (Zn). Preferably, the first circuit pattern layer 421, the second circuit pattern layer 422, the third circuit pattern layer 423, and the fourth circuit pattern layer 424 may be formed of copper (Cu), which has high electrical conductivity and is relatively inexpensive.

Meanwhile, the first circuit pattern layer 421, the second circuit pattern layer 422, the third circuit pattern layer 423, and the fourth circuit pattern layer 424 can be manufactured using conventional circuit board manufacturing processes such as an additive process, a subtractive process, a modified semi-additive process (MSAP), and a semi-additive process (SAP), and a detailed description thereof is omitted herein.

The circuit board 400 of the embodiment may include a through electrode. The through electrode may penetrate the insulating layer 410.

For example, the through electrode may include a through electrode 431 penetrating the first insulating layer 411, a through electrode 432 penetrating the second insulating layer 412, and a through electrode 433 penetrating the third insulating layer 413.

The through electrode 431 can electrically connect between the first circuit pattern layer 421 and the third circuit pattern layer 423.

In addition, the through electrode 432 can electrically connect between the first circuit pattern layer 421 and the second circuit pattern layer 422.

In addition, the through electrode 433 can electrically connect between the third circuit pattern layer 423 and the fourth circuit pattern layer 424.

The through electrodes 431, 432, and 433 can be formed by filling the inside of a through hole penetrating the insulating layer 410 with a conductive material.

The through hole can be formed by any one of mechanical, laser, and chemical processing methods. When the through hole is formed by mechanical processing, methods such as milling, drilling, and routing can be used. In addition, when the through hole is formed by laser processing, a UV or CO2 laser method can be used. In addition, when the through hole is formed by chemical processing, a chemical agent including amino silane, ketones, etc. can be used.

At this time, at least one of the through electrodes can be formed by a process different from at least one other through electrode.

For example, the first insulating layer 411 includes an insulating material different from the second insulating layer 412 and the third insulating layer 413.

That is, the first insulating layer 411 includes a thermosetting resin. Accordingly, a through hole can be formed in the first insulating layer 411 by a laser processing method.

Differently, the second insulating layer 412 and the third insulating layer 413 include a photocurable resin. Accordingly, a through hole can be formed in the second insulating layer 412 and the third insulating layer 413 by a chemical processing method through an exposure and development process.

Accordingly, the through electrodes 432 and 433 penetrating the second insulating layer 412 and the third insulating layer 413 may have a smaller width than the through electrode 431 penetrating the first insulating layer 411. Furthermore, a difference between upper and lower widths of the through electrodes 432 and 433 penetrating the second insulating layer 412 and the third insulating layer 413 may be smaller than a difference between upper and lower widths of the through electrode 431 penetrating the first insulating layer 411.

Meanwhile, the circuit board 400 of the embodiment may include a protective layer.

For example, the circuit board 400 may include a first protective layer 450 disposed on the second insulating layer 412. For example, the circuit board 400 may include a second protective layer 460 disposed under the third insulating layer 413.

The first protective layer 450 and the second protective layer 460 may be a resist layer. Preferably, the first protective layer 450 and the second protective layer 460 may be a solder resist layer containing an organic polymer material. For example, the first protective layer 450 and the second protective layer 460 may contain an epoxy acrylate series resin. In detail, the first protective layer 450 and the second protective layer 460 may contain a resin, a curing agent, a pigment, a solvent, a filler, an additive, an acrylic series monomer, etc.

A total thickness of each of the first protective layer 450 and the second protective layer 460 may be greater than a thickness of each of the second circuit pattern layer 422 and the fourth circuit pattern layer 424. The total thickness may mean a vertical distance between the lower surface and the upper surface of the first protective layer 450 and the second protective layer 460.

The total thickness of the first protective layer 450 may satisfy a range of 6.7 um to 35.0 um. Preferably, the total thickness of the first protective layer 450 may satisfy a range of 7.3 um to 32 um. More preferably, the total thickness of the first protective layer 450 may satisfy a range of 8.0 um to 30 um.

If the total thickness of the first protective layer 450 exceeds 30 um, the thickness of the circuit board and the thickness of the semiconductor package may increase. In addition, if the total thickness of the first protective layer 450 is less than 6.7 um, the second circuit pattern layer 422 may not be stably protected, and thus, electrical reliability or physical reliability may be degraded.

In addition, the second protective layer 460 may have a thickness corresponding to the thickness of the first protective layer 450, but is not limited thereto.

The first protective layer 450 and the second protective layer 460 may each include an opening.

For example, the first protective layer 450 may include a first opening. The first opening may vertically overlap at least a portion of the second circuit pattern layer 422. As a result, the first opening of the first protective layer 450 may expose at least a portion of the upper surface of the second circuit pattern layer 422.

In addition, the second protective layer 460 may include a second opening. The second opening may vertically overlap at least a portion of the lower surface of the fourth circuit pattern layer 424. For example, the second opening may expose at least a portion of the lower surface of the fourth circuit pattern layer 424.

Meanwhile, the circuit board of the embodiment may include a buffer layer. The buffer layer may be referred to as an oxide layer. The buffer layer may be disposed in at least one of between different insulating layers, between an insulating layer and a circuit pattern layer, between an insulating layer and a through electrode, between an insulating layer and a protective layer, and between a circuit pattern layer and a protective layer.

Specifically, the first insulating layer 411 and the second insulating layer 412 of the embodiment include different insulating materials. In addition, the first insulating layer 411 and the third insulating layer 413 of the embodiment include different insulating materials.

Accordingly, in a process of laminating the second insulating layer 412 on the first insulating layer 411, an adhesion between the first insulating layer 411 and the second insulating layer 412 may be reduced. Furthermore, the adhesion between the first circuit pattern layer 421 disposed on the first insulating layer 411 and the second insulating layer 412 may be reduced.

In addition, in a process of laminating the third insulating layer 413 under the first insulating layer 411, an adhesion between the first insulating layer 411 and the third insulating layer 413 may be reduced. Furthermore, the adhesion between the third circuit pattern layer 423 disposed under the first insulating layer 411 and the third insulating layer 413 may be reduced.

Specifically, the first insulating layer 411 may include a thermosetting resin. In addition, the second insulating layer 412 and the third insulating layer 413 may include a photocurable resin. For example, the second insulating layer 412 and the third insulating layer 413 may include a PID. That is, the second insulating layer 412 can be referred to a photosensitive insulating layer, and the first insulating layer 411 can be referred to an additional insulating layer disposed under the second insulating layer 412. In addition, the third insulating layer 413 can be referred to another photosensitive insulating layer disposed under the first insulating layer 411.

The photocurable resin has a higher curing shrinkage rate than the thermosetting resin. Furthermore, a content of ceramic particles such as SiO2 inside the photocurable resin is higher than that of the thermosetting resin.

At this time, when analyzing the photocurable resin through XPS (X-ray Photoelectron Spectroscopy), relatively high power peaks can be detected in two of acrylic and epoxy. In addition, when analyzing the thermosetting resin that does not include reinforcing fibers through XPS, high power peaks can be detected only in the epoxy. Accordingly, it is possible to distinguish between the photocurable resin that does not include reinforcing fibers and the thermosetting resin.

Meanwhile, when the second insulating layer 412 is composed of a photocurable resin, the adhesion between the first insulating layer 411 and the second insulating layer 412 may be reduced. Furthermore, the adhesion between the first circuit pattern layer 421 and the second insulating layer 412 may be reduced.

In addition, the circuit pattern layer applied to recent circuit boards has low surface roughness in order to minimize signal transmission loss in a high-frequency band. For example, as the frequency band increases, the signal has the characteristic of flowing along the surface of the circuit pattern layer. In addition, when the surface roughness of the circuit pattern layer is high, the signal transmission loss also increases.

In addition, as the surface roughness of the circuit pattern layer decreases, the adhesion with the second insulating layer 412 decreases.

Correspondingly, the adhesion between the first insulating layer 411 and the third insulating layer 413 may be reduced, and the adhesion between the third circuit pattern layer 423 and the third insulating layer 413 may be reduced.

Accordingly, a first buffer layer 441 may be disposed on the first insulating layer 411 of the embodiment. The first buffer layer 441 may be disposed between the first insulating layer 411 and the second insulating layer 412. Through this, the embodiment may improve the adhesion between the first insulating layer 411 and the second insulating layer 412. The first buffer layer 441 may be referred to as a lower oxide layer.

Furthermore, the first buffer layer 441 may be disposed between the first circuit pattern layer 421 and the second insulating layer 412. Through this, the first buffer layer 441 may improve the adhesion between the first circuit pattern layer 421 and the second insulating layer 412.

In addition, at least a part of the first buffer layer 441 may be in contact with the through electrode 432 penetrating the second insulating layer 412. Through this, the first buffer layer 441 may improve the adhesion of the through electrode 432.

Meanwhile, the first buffer layer 441 may include at least one open region. Preferably, the first buffer layer 441 may open a region of the upper surface of the first circuit pattern layer 421 that vertically overlaps with the through electrode 432. That is, when the first buffer layer 441 is disposed between the first circuit pattern layer 421 and the through electrode 432, the electrical characteristics between the first circuit pattern layer 421 and the through electrode 432 may be deteriorated. Therefore, the first buffer layer 441 includes an open region that opens a region vertically overlapping the through electrode 432 on the upper surface of the first circuit pattern layer 421. Accordingly, the through electrode 432 is disposed in the open region of the first buffer layer 441, and thus can directly contact the upper surface of the first circuit pattern layer 421. Accordingly, the through electrode 432 can have a structure that penetrates the first buffer layer 441 together with the second insulating layer 412.

Meanwhile, a second buffer layer 442 may be disposed on the second insulating layer 412. The second buffer layer 442 may be referred to as an upper oxide layer.

The second buffer layer 442 may be disposed between the second insulating layer 412 and the first protective layer 450. Through this, the embodiment may improve the adhesion between the second insulating layer 412 and the first protective layer 450.

Furthermore, the second buffer layer 442 may be disposed between the second circuit pattern layer 422 and the first protective layer 450. Through this, the embodiment may improve the adhesion between the second circuit pattern layer 422 and the first protective layer 450.

In addition, the second buffer layer 442 may be disposed on an inner wall of the through hole penetrating the second insulating layer 412. For example, the second buffer layer 442 may be disposed between the through hole of the second insulating layer 412 and the through electrode 432. Through this, the second buffer layer 442 may improve the adhesion between the second insulating layer 412 and the through electrode 432.

Meanwhile, the second buffer layer 442 may include at least one open region. For example, the second buffer layer 442 may include an open region vertically overlapping the first opening of the first protective layer 450. For example, the second buffer layer 442 may include an open region that opens at least a portion of the upper surface of the second circuit pattern layer 422. For example, the second buffer layer 442 may include an open region that exposes a pad region coupled to a semiconductor device or an external substrate on the upper surface of the second circuit pattern layer 422. At this time, although the second buffer layer 442 is said to include an open region, it is not limited thereto. For example, a connection member may be disposed in the pad region, and a reflow process of the connection member may be performed. In addition, the second buffer layer 442 disposed on the pad region may be removed in the reflow process. Therefore, the embodiment may not form a separate open region in the second buffer layer 442.

In addition, a third buffer layer 443 may be disposed under the first insulating layer 411.

The third buffer layer 443 may be disposed between the first insulating layer 411 and the third insulating layer 413. Through this, the embodiment may improve the adhesion between the first insulating layer 411 and the third insulating layer 413.

In addition, the third buffer layer 443 may be disposed between the third circuit pattern layer 423 and the third insulating layer 413. Through this, the third buffer layer 443 may improve the adhesion between the third circuit pattern layer 423 and the third insulating layer 413.

In addition, at least a part of the third buffer layer 443 may be in contact with the through electrode 433 penetrating the third insulating layer 413. Through this, the third buffer layer 443 may improve the adhesion with the through electrode 433.

Meanwhile, the third buffer layer 443 may include at least one open region. Preferably, the third buffer layer 443 may open a region of the lower surface of the third circuit pattern layer 423 that vertically overlaps with the through electrode 433. That is, when the third buffer layer 443 is disposed between the third circuit pattern layer 423 and the through electrode 433, the electrical characteristics between the third circuit pattern layer 423 and the through electrode 433 may be deteriorated. Therefore, the third buffer layer 443 includes an open region that opens a region vertically overlapping the through electrode 433 on the lower surface of the third circuit pattern layer 423. Accordingly, the through electrode 433 is disposed in the open region of the third buffer layer 443, and thus may directly contact the lower surface of the third circuit pattern layer 423. Accordingly, the through electrode 433 may have a structure that penetrates the third buffer layer 443 together with the third insulating layer 413.

Meanwhile, a fourth buffer layer 444 may be disposed under the third insulating layer 413.

The fourth buffer layer 444 may be disposed between the third insulating layer 413 and the second protective layer 460. Through this, the embodiment may improve the adhesion between the third insulating layer 413 and the second protective layer 460.

Furthermore, the fourth buffer layer 444 may be disposed between the fourth circuit pattern layer 424 and the second protective layer 460. Through this, the embodiment may improve the adhesion between the fourth circuit pattern layer 424 and the second protective layer 460.

In addition, the fourth buffer layer 444 may be disposed on an inner wall of the through hole penetrating the third insulating layer 413. For example, the fourth buffer layer 444 may be disposed between the through hole of the third insulating layer 413 and the through electrode 433. Through this, the fourth buffer layer 444 can improve the adhesion between the third insulating layer 413 and the through electrode 433.

Meanwhile, the fourth buffer layer 444 can include at least one open region. For example, the fourth buffer layer 444 can include an open region vertically overlapping the second opening of the second protective layer 460. For example, the fourth buffer layer 444 can include an open region that opens at least a portion of the lower surface of the fourth circuit pattern layer 424. For example, the fourth buffer layer 444 can include an open region that exposes a pad region coupled to a semiconductor device or an external substrate among the lower surfaces of the fourth circuit pattern layer 424. At this time, although the fourth buffer layer 444 is said to include an open region, it is not limited thereto. For example, a connection member may be disposed in the pad region, and a reflow process of the connection member may be performed. In addition, the fourth buffer layer 444 disposed on the pad region can be removed in the reflow process. Therefore, the embodiment may not form a separate open region in the fourth buffer layer 444.

Meanwhile, each of the first to fourth buffer layers 441, 442, 443, and 444 may include an oxide. For example, each of the first to fourth buffer layers 441, 442, 443, and 444 may be an oxide layer including an oxide. Preferably, the first to fourth buffer layers 441, 442, 443, and 444 may include aluminum oxide (Al₂O₃). However, the embodiment is not limited thereto, and the first to fourth buffer layers 441, 442, 443, and 444 may include a material including at least one reactive group or functional group that reacts with the insulating layer or the protective layer.

Each of the first to fourth buffer layers 441, 442, 443, and 444 may have a thickness in a range of 5 nm to 100 nm. Preferably, each of the first to fourth buffer layers 441, 442, 443, and 444 may have a thickness in a range of 7 nm to 90 nm. More preferably, each of the first to fourth buffer layers 441, 442, 443, and 444 may have a thickness in a range of 10 nm to 50 nm.

If the thickness of each of the first to fourth buffer layers 441, 442, 443, and 444 is less than 5 nm, it may not be possible to form a buffer layer of uniform thickness on the insulating layer or circuit pattern layer. In addition, if the buffer layer does not have a uniform thickness, the adhesion may be reduced in a specific region. In addition, if the thickness of each of the first to fourth buffer layers 441, 442, 443, and 444 is less than 5 nm, the effect of improving the adhesion achieved according to the embodiment may be insignificant.

In addition, if the thickness of the first to fourth buffer layers 441, 442, 443, and 444 exceeds 100 nm, a time for forming the first to fourth buffer layers 441, 442, 443, and 444 may increase and the product yield may decrease accordingly.

Meanwhile, each of the first to fourth buffer layers 441, 442, 443, and 444 may be formed by applying a deposition method of ALD (Atomic Layer Deposition) or CVD (Chemical Vapor Deposition), but is not limited thereto.

As described above, the embodiment includes a buffer layer. The buffer layer is disposed between a plurality of insulating layers including different insulating materials.

At this time, if the plurality of insulating layers are formed with a same insulating material, it can be said that the buffer layer can be omitted. However, even if the plurality of insulating layers include the same insulating material, it is preferable to provide the buffer layer due to the characteristics of the circuit board having low surface roughness applied to the high-frequency band.

Furthermore, if all of the plurality of insulating layers are applied as prepregs, there is a problem that the overall thickness of the circuit board increases. That is, reinforcing fibers are included in the prepreg, and thus there is a limit to reducing a thickness of the insulating layer. As a result, there is a problem that the overall thickness of the circuit board and the semiconductor package increases.

Furthermore, if all of the plurality of insulating layers are applied as insulating layers that do not include reinforcing fibers, there is a problem that the bending characteristics of the circuit board deteriorate. That is, if the reinforcing fibers are not included in the insulating layer, the warpage characteristics of the insulating layer deteriorate, and thus the process characteristics in the process of manufacturing the circuit board may deteriorate.

In addition, there is a limit to reducing a shape and size of the through electrode with only thermosetting resin. As a result, the circuit board may include a photocurable resin. In addition, the adhesion with the thermosetting resin or the circuit pattern layer may be reduced due to the characteristics of the photocurable resin.

Therefore, the embodiment applies the first to fourth buffer layers 441, 442, 443, and 444 as described above so as to improve the adhesion between each layer constituting the circuit board as a whole.

Hereinafter, an arrangement structure of the first to fourth buffer layers 441, 442, 443, and 444 will be described in more detail.

However, the following description will focus on the first buffer layer 441 and the second buffer layer 442. In addition, the third buffer layer 443 and the fourth buffer layer 444 may have an arrangement structure corresponding to the first buffer layer 441 and the second buffer layer 442 described below.

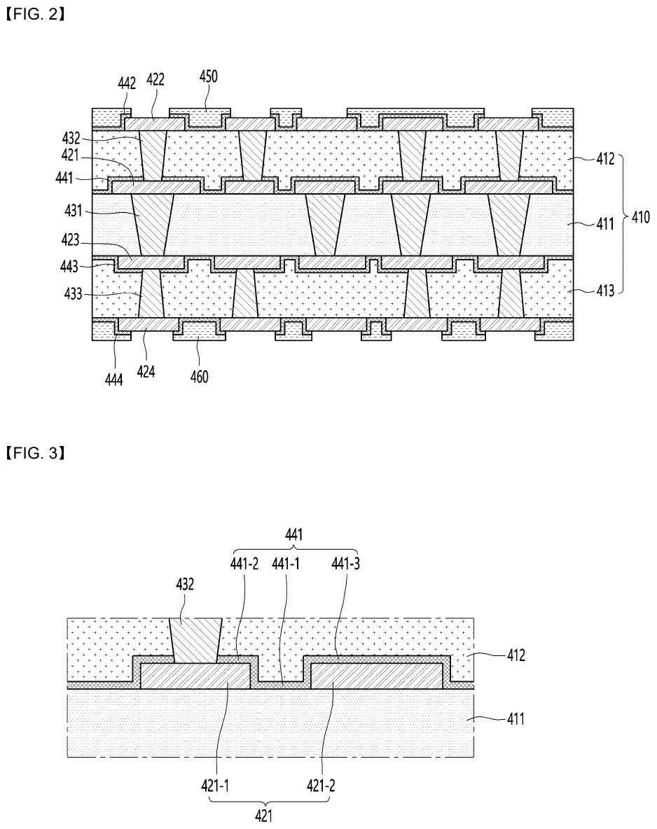

FIG. 3 is a cross-sectional view explaining an arrangement structure of a first buffer layer according to one embodiment.

Referring to FIG. 3, a first buffer layer 441 is disposed on the first insulating layer 411. At this time, the first buffer layer 441 may include a plurality of portions.

The first buffer layer 441 may be formed after the first circuit pattern layer 421 is disposed on the first insulating layer 411. Therefore, the first buffer layer 441 may not be provided between the first insulating layer 411 and the first circuit pattern layer 421.

The first buffer layer 441 may include a first portion 441-1. The first portion 441-1 of the first buffer layer 441 may mean a region disposed on the upper surface of the first insulating layer 411 among an entire region of the first buffer layer 441.

The first portion 441-1 of the first buffer layer 441 may be disposed between an upper surface of the first insulating layer 411 and a lower surface of the second insulating layer 412. Through this, the first portion 441-1 of the first buffer layer 441 may improve the adhesion between the first insulating layer 411 and the second insulating layer 412.

In addition, the first buffer layer 441 may include a second portion 441-2 and a third portion 441-3.

The second portion 441-2 and the third portion 441-3 of the first buffer layer 441 may mean a region disposed on a surface of the first circuit pattern layer 421 among the entire region of the first buffer layer 441.

At this time, the second portion 441-2 and the third portion 441-3 of the first buffer layer 441 may have different arrangement structures. For example, the second portion 441-2 of the first buffer layer 441 may include an open region, and the third portion 441-3 of the first buffer layer 441 may not include an open region.

For example, the first circuit pattern layer 421 may include a plurality of patterns. For example, the first circuit pattern layer 421 may include a first pattern 421-1 and a second pattern 421-2.

The first pattern 421-1 of the first circuit pattern layer 421 may mean a pattern in direct contact with the through electrode 432 among the first circuit pattern layers 421. For example, the first pattern 421-1 of the first circuit pattern layer 421 may mean a pattern vertically overlapping the through electrode 432.

In addition, the second pattern 421-2 of the first circuit pattern layer 421 may mean a pattern that does not directly contact the through electrode 432 among the first circuit pattern layers 421. For example, the second pattern 421-2 of the first circuit pattern layer 421 may mean a pattern that does not vertically overlap the through electrode 432.

The second portion 441-2 of the first buffer layer 441 may partially cover the surface of the first pattern 421-1 of the first circuit pattern layer 421. For example, the second portion 441-2 of the first buffer layer 441 may entirely cover a side surface of the first pattern 421-1. For example, the second portion 441-2 of the first buffer layer 441 may partially cover the upper surface of the first pattern 421-1. For example, the second portion 441-2 of the first buffer layer 441 may be selectively disposed in a region of the upper surface of the first pattern 421-1 that does not vertically overlap with the through electrode 432. For example, the second portion 441-2 of the first buffer layer 441 may include an open region that is disposed on the upper surface of the first pattern 421-1 and vertically overlaps with the through electrode 432. Accordingly, the through electrode 432 may be disposed in the open region of the second portion 441-2 of the first buffer layer 441, thereby making direct contact with the upper surface of the first pattern 421-1 of the first circuit pattern layer 421. For example, the through electrode 432 may penetrate the second portion 441-2 of the first buffer layer 441 while penetrating the second insulating layer 412. In addition, at least a part of the side surface of the through electrode 432 may be in contact with the second portion 441-2 of the first buffer layer 441.

Accordingly, the second portion 441-2 of the first buffer layer 441 may function of improving the adhesion between the first pattern 421-1 of the first circuit pattern layer 421 and the second insulating layer 412. Furthermore, the second portion 441-2 of the first buffer layer 441 may function of improving the adhesion between the first pattern 421-1 of the first circuit pattern layer 421 and the through electrode 432.

Meanwhile, the third portion 441-3 of the first buffer layer 441 may not include an open region. For example, the third portion 441-3 of the first buffer layer 441 may entirely cover the side surface and the upper surface of the second pattern 421-2 of the first circuit pattern layer 421. Accordingly, the second pattern 421-2 of the first circuit pattern layer 421 may not directly contact the second insulating layer 412. For example, the lower surface of the second pattern 421-2 of the first circuit pattern layer 421 may contact the first insulating layer 411, and the side surface and the upper surface of the second pattern 421-2 of the first circuit pattern layer 421 may contact the first buffer layer 441.

The embodiment can improve the adhesion between the first insulating layer 411 and the second insulating layer 412, the adhesion between the first circuit pattern layer 421 and the second insulating layer 412, and further the adhesion between the first circuit pattern layer 421 and the through electrode 432 by using the first buffer layer 441.

FIG. 4 is a cross-sectional view explaining an arrangement structure of a second buffer layer according to a first embodiment.

Referring to FIG. 4, the second buffer layer 442 is disposed on the second insulating layer 412. At this time, when the second insulating layer 412 is composed of a plurality of layers, the second buffer layer 442 can be disposed between a plurality of second insulating layers. Hereinafter, the second buffer layer disposed on the second insulating layer disposed adjacent to the first protective layer 450 will be described.

The second buffer layer 442 may be disposed between the second insulating layer 412 and the first protective layer 450. In addition, the second buffer layer 442 may be disposed between the second circuit pattern layer 422 and the first protective layer 450.

That is, the second buffer layer 442 of the first embodiment may be formed in a state in which the second circuit pattern layer 422 is disposed on the second insulating layer 412. Accordingly, the second buffer layer 442 of the first embodiment may not be disposed between the second insulating layer 412 and the second circuit pattern layer 422.

The second buffer layer 442 may include a plurality of portions.

The second buffer layer 442 may include a first portion 442-1. The first portion 442-1 of the second buffer layer 442 may refer to a region disposed on the upper surface of the second insulating layer 412 among an entire region of the second buffer layer 442.

The first portion 442-1 of the second buffer layer 442 may be disposed between the upper surface of the second insulating layer 412 and the lower surface of the first protective layer 450. Through this, the first portion 442-1 of the second buffer layer 442 may improve the adhesion between the second insulating layer 412 and the first protective layer 450.

In addition, the second buffer layer 442 may include a second portion 442-2 and a third portion 442-3.

The second portion 442-2 and the third portion 442-3 of the second buffer layer 442 may refer to a region disposed on the surface of the second circuit pattern layer 422 among the entire region of the second buffer layer 442.

At this time, the second portion 442-2 and the third portion 442-3 of the second buffer layer 442 may have different arrangement structures. For example, the second portion 442-2 of the second buffer layer 442 may include an open region, and the third portion 442-3 of the second buffer layer 442 may not include an open region.

For example, the second circuit pattern layer 422 may include a plurality of patterns. For example, the second circuit pattern layer 422 may include a first pattern 422-1 and a second pattern 422-2.

The first pattern 422-1 of the second circuit pattern layer 422 may mean a pattern of the second circuit pattern layer 422 vertically overlapping the first opening 451 of the first protective layer 450. For example, the first pattern 422-1 of the second circuit pattern layer 422 may mean a pad coupled with a semiconductor device or an external substrate.

In addition, the second pattern 422-2 of the second circuit pattern layer 422 may mean a pattern that does not vertically overlap with the first opening 451 of the first protective layer 450 of the second circuit pattern layer 422.

The second portion 442-2 of the second buffer layer 442 may partially cover the surface of the first pattern 422-1 of the second circuit pattern layer 422. For example, the second portion 442-2 of the second buffer layer 442 may entirely cover the side surface of the first pattern 422-1 of the second circuit pattern layer 422. For example, the second portion 442-2 of the second buffer layer 442 may partially cover the upper surface of the first pattern 422-1 of the second circuit pattern layer 422. For example, the second portion 442-2 of the second buffer layer 442 may be selectively disposed in a region of the upper surface of the first pattern 422-1 of the second circuit pattern layer 422 that does not vertically overlap with the first opening 451 of the first protective layer 450. For example, the second portion 442-2 of the second buffer layer 442 may include an open region that is disposed on the upper surface of the first pattern 422-1 of the second circuit pattern layer 422 and vertically overlaps the first opening 451 of the first protective layer 450.

Accordingly, the second portion 442-2 of the second buffer layer 442 may have a function of improving the adhesion between the first pattern 422-1 of the second circuit pattern layer 422 and the first protective layer 450.

Meanwhile, the third portion 442-3 of the second buffer layer 442 may not include an open region. For example, the third portion 442-3 of the second buffer layer 442 may entirely cover the side surface and the upper surface of the second pattern 422-2 of the second circuit pattern layer 422. Through this, the second pattern 422-2 of the second circuit pattern layer 422 may not directly contact the first protective layer 450. For example, the lower surface of the second pattern 422-2 of the second circuit pattern layer 422 may contact the second insulating layer 412, and the side surface and upper surface of the second pattern 422-2 of the second circuit pattern layer 422 may contact the second buffer layer 442.

The embodiment can improve the adhesion between the second insulating layer 412 and the first protective layer 450, and the adhesion between the second circuit pattern layer 422 and the first protective layer 450 by using the second buffer layer 442.

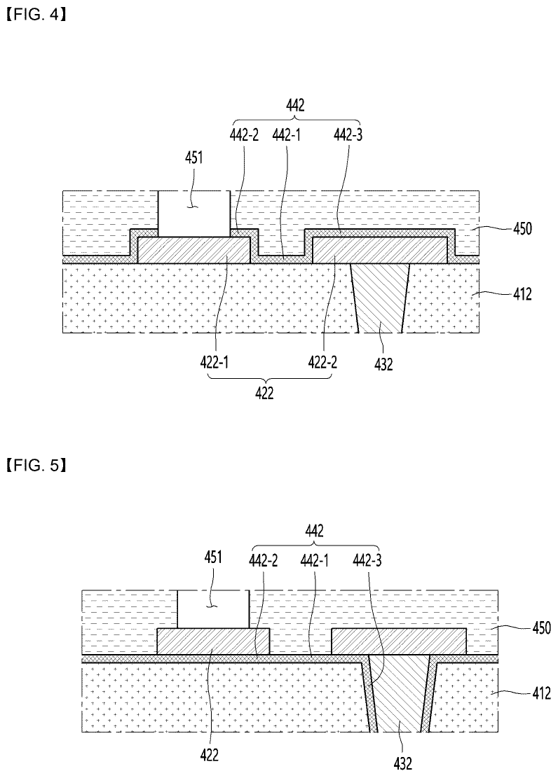

FIG. 5 is a cross-sectional view explaining an arrangement structure of a second buffer layer according to a second embodiment.

Referring to FIG. 5, the second buffer layer 442 is disposed on the second insulating layer 412.

The second buffer layer 442 may be disposed between the second insulating layer 412 and the first protective layer 450. In addition, the second buffer layer 442 may be disposed between the second insulating layer 412 and the first protective layer 450.

That is, the second buffer layer 442 of the second embodiment is disposed on the second insulating layer 412 before the second circuit pattern layer 422 is formed. Preferably, the second buffer layer 442 may be formed after a through hole is formed in the second insulating layer 412 and before the through electrode 432 and the second circuit pattern layer 422 are formed.

Therefore, the second buffer layer 442 of the second embodiment may not be disposed between the second circuit pattern layer 422 and the first protective layer 450. However, the embodiment is not limited thereto. For example, the embodiment may perform a process of forming the second buffer layer 442 multiple times. Accordingly, the second buffer layer 442 may have a combination of a structure of the second embodiment described below and the structure of the first embodiment described above.

The second buffer layer 442 may include a plurality of portions.

The second buffer layer 442 may include a first portion 442-1. The first portion 442-1 of the second buffer layer 442 may mean a region disposed between the second insulating layer 412 and the first protective layer 450 among the entire region of the second buffer layer 442.

The first portion 442-1 of the second buffer layer 442 may be disposed between the upper surface of the second insulating layer 412 and the lower surface of the first protective layer 450. Through this, the first portion 442-1 of the second buffer layer 442 may improve the adhesion between the second insulating layer 412 and the first protective layer 450.

In addition, the second buffer layer 442 may include a second portion 442-2 and a third portion 442-3.

The second portion 442-2 of the second buffer layer 442 may mean a region disposed between the second insulating layer 412 and the second circuit pattern layer 442-2 among an entire region of the second buffer layer 442. Through this, the second portion 442-2 of the second buffer layer 442 can improve the adhesion between the second insulating layer 412 and the second circuit pattern layer 442-2.

In addition, the third portion 442-3 of the second buffer layer 442 can be disposed on an inner wall of the through hole of the second insulating layer 412. That is, the second buffer layer 442 is formed after the through hole is formed in the second insulating layer 412. Therefore, the second buffer layer 442 can include a third portion 442-3 provided on an inner wall of the through hole of the second insulating layer 412.

The third portion 442-3 of the second buffer layer 442 is disposed between the second insulating layer 412 and the through electrode 432. Through this, the third portion 442-3 of the second buffer layer 442 can improve the adhesion between the second insulating layer 412 and the through electrode 432.

The circuit board of the embodiment can improve an adhesion between a plurality of layers.

Specifically, the circuit board of the embodiment comprises a first insulating layer including a first insulating material, and a second insulating layer disposed on the first insulating layer and including a second insulating material different from the first insulating material.

At this time, the embodiment includes a buffer layer disposed between the first insulating layer and the second insulating layer. The buffer layer can function as an adhesive layer that improves the adhesion between the first insulating layer and the second insulating layer. The buffer layer can be an oxide layer. For example, the buffer layer can include aluminum oxide.

Through this, the embodiment can improve the adhesion between the first insulating layer and the second insulating layer, thereby improving the physical reliability and/or electrical reliability of the circuit board and the semiconductor package including the same.

Furthermore, the first insulating layer can include a thermosetting resin, and the second insulating layer can include a photocurable resin. The embodiment can improve the physical and electrical reliability of the circuit pattern layer and the through electrode disposed on the second insulating layer by the second insulating layer including the photocurable resin. Furthermore, the circuit pattern layer and the through electrode disposed on the second insulating layer can be miniaturized by the second insulating layer including the photocurable resin.

At this time, the photocurable resin has a relatively high ceramic particle content and a relatively high curing shrinkage rate. Accordingly, there may be a problem that the adhesion between the photocurable resin and other layers is reduced.

In contrast, the embodiment includes a buffer layer disposed on a surface of the photocurable resin. Accordingly, the embodiment can miniaturize the circuit pattern layer and the through electrode without affecting the adhesion even if the second insulating layer includes the photocurable resin.

Therefore, the embodiment can improve a circuit integration of the circuit board, and further improve the physical and/or electrical reliability of the circuit board.

Meanwhile, the buffer layer of the embodiment is also disposed between the second insulating layer and the circuit pattern layer. Accordingly, the embodiment can improve the adhesion between the second insulating layer and the circuit pattern layer.

In addition, the buffer layer of the embodiment is also disposed between the second insulating layer and the through electrode. Accordingly, the embodiment can improve the adhesion between the second insulating layer and the through electrode.

In addition, the buffer layer of the embodiment is also disposed between the second insulating layer and a first protective layer. Accordingly, the embodiment can improve the adhesion between the second insulating layer and the first protective layer.

In addition, the buffer layer of the embodiment is also disposed between the circuit pattern layer and the first protective layer. Accordingly, the embodiment can improve the adhesion between the circuit pattern layer and the first protective layer.

The embodiment can improve the adhesion between a plurality of layers constituting the circuit board by forming a buffer layer having a structure as described above, and can improve product reliability accordingly.

FIG. 6 is a drawing showing a circuit board according to a second embodiment.

Referring to FIG. 6, the circuit board of the second embodiment may have a structure that is generally similar to the circuit board of the first embodiment of FIG. 2. However, the circuit board of the second embodiment may be provided with a cavity C in a second insulating layer compared to the circuit board of the first embodiment. Accordingly, the circuit board of the second embodiment may be distinguished from the circuit board of the first embodiment in a structure of the second insulating layer including the cavity C and the second buffer layer disposed in the second insulating layer.

Hereinafter, a circuit board of a second embodiment will be described, focusing on a feature distinguished from the circuit board of the first embodiment.

The circuit board includes a first insulating layer 511 and a second insulating layer 512. A first circuit pattern layer 521 is disposed on the first insulating layer 511.

In addition, although omitted in the drawing, a first buffer layer may be disposed on the first insulating layer 511.

Meanwhile, a second buffer layer 542 is disposed on the second insulating layer 512. At this time, an arrangement structure of the second buffer layer 542 may be similar to the structure illustrated in FIG. 5.

However, the second insulating layer 512 includes a cavity C. Accordingly, the second buffer layer 542 may include a portion additionally formed in a region corresponding to the cavity C.

That is, the second insulating layer 512 includes a cavity C penetrating the upper and lower surfaces. At this time, the cavity C of the second insulating layer 512 may be formed together with a through hole corresponding to a through electrode 532 penetrating the second insulating layer 512.

The first circuit pattern layer 521 further includes a third pattern 521-3 vertically overlapping the cavity C.

A third pattern 521-3 of the first circuit pattern layer 521 may include an upper surface exposed through the cavity C. The third pattern 521-3 of the first circuit pattern layer 521 may be a semiconductor device disposed in the cavity C or a pad coupled to an external substrate.

Meanwhile, the second buffer layer 542 disposed on the second insulating layer 512 may include a plurality of portions.

The second buffer layer 542 may include a first portion 542-1 disposed between the second insulating layer 512 and the first protective layer 550.

In addition, the second buffer layer 542 may include a second portion 542-2 disposed between an inner wall of the through hole of the second insulating layer 512 and the through electrode 532.

In addition, the second buffer layer 542 may include a third portion 542-3 disposed on an inner wall of the cavity C of the second insulating layer 512.

In addition, the second buffer layer 542 may include a fourth portion 542-4 disposed on a lower surface of the cavity C of the second insulating layer 512. At this time, the fourth portion 542-4 of the second buffer layer 542 may be a part of the first buffer layer described above.

The second buffer layer 542 included in the circuit board of the second embodiment includes a third portion 542-3 disposed on the inner wall of the cavity C and a fourth portion 542-4 disposed on the lower surface of the cavity C, which is different from the circuit board of the first embodiment.

The third portion 542-3 of the second buffer layer 542 is disposed on the inner wall of the cavity C. At this time, the embodiment can prevent debris from being exposed through the inner wall of the cavity C by using the third portion 542-3 of the second buffer layer 542. For example, when forming the cavity C in the second insulating layer 512, debris such as a burr may exist on the inner wall of the cavity C depending on a processing process of the cavity C.

Accordingly, in a conventional technology, a de-smear process was additionally performed to remove the debris.

In contrast, the embodiment forms the third portion 542-3 of the second buffer layer 542 on the inner wall of the cavity C. Accordingly, the embodiment can solve the reliability problem that may occur due to the debris through the third portion 542-3 of the second buffer layer 542. Furthermore, the embodiment can omit the de-smear process by arranging the third portion 542-3 of the second buffer layer 542, thereby simplifying the manufacturing process.

In addition, the embodiment includes a fourth portion 542-4 of the second buffer layer 542 disposed on the lower surface of the cavity C. At this time, the lower surface of the cavity C substantially corresponds to the upper surface of the first insulating layer 511. Accordingly, the fourth portion 542-4 of the second buffer layer 542 may also be referred to as a portion of the first buffer layer 441 described in the previous embodiment.

The fourth portion 542-4 of the second buffer layer 542 is disposed on the lower surface of the cavity C, and thus, a portion of the insulating material included in the first insulating layer 511 may be prevented from being exposed through the cavity C.

For example, when a de-smear process is performed after forming the cavity C, a surface of the first insulating layer 511 may also be removed during the de-smear process. In addition, a portion of the reinforcing fiber disposed within the first insulating layer 511 may be exposed through the cavity C during the de-smear process. In addition, if the reinforcing fiber is exposed through the cavity C, physical reliability or electrical reliability problems may occur during the mounting process of the semiconductor device or the bonding process of an external substrate.

In contrast, in the embodiment, the fourth part 542-4 of the second buffer layer 542 is disposed on the lower surface of the cavity C. In addition, the fourth part 542-4 of the second buffer layer 542 can function as a barrier layer that protects a surface of the first insulating layer 511 in the de-smear process. Through this, the embodiment can prevent the reinforcing fiber included in the first insulating layer 511 from being exposed through the cavity C, thereby improving the overall physical and electrical reliability of the circuit board.

Meanwhile, the fourth portion 542-4 of the second buffer layer 542 can include an open region that exposes the surface of the third pattern 521-3 of the first circuit pattern layer 521. For example, the fourth portion 542-4 of the second buffer layer 542 may entirely expose the upper surface of the third pattern 521-3 of the first circuit pattern layer 521. Furthermore, the fourth portion 542-4 of the second buffer layer 542 may expose at least a part of the side surface of the third pattern 521-3 of the first circuit pattern layer 521.

Meanwhile, in the drawing, the cavity C is illustrated as penetrating the second insulating layer 512 of one layer, but is not limited thereto. For example, the cavity C may also penetrate the second insulating layer of at least two layers.

As described above, the circuit board according to the second embodiment may include a cavity and thus improve the overall product reliability of the circuit board.

That is, the second insulating layer includes a cavity. At this time, the buffer layer can also be disposed on an inner wall of the cavity of the second insulating layer. Accordingly, the embodiment can omit a de-smear process for removing debris remaining on the inner wall of the cavity. Accordingly, the embodiment can simplify a manufacturing process of the circuit board. Furthermore, the embodiment can prevent a size of the cavity from being expanded by the de-smear process by omitting the de-smear process, thereby forming a cavity having an optimal size. Accordingly, the embodiment can reduce a volume of the circuit board.

In addition, the buffer layer can also be disposed on a lower surface of the cavity. In addition, if the de-smear process is performed after forming the cavity, the buffer layer disposed on a lower surface of the cavity can function as a barrier layer. In addition, the embodiment can prevent a reinforcing fiber included in the first insulating layer from being exposed by the barrier layer in the de-smear process. Accordingly, the embodiment can further improve product reliability.

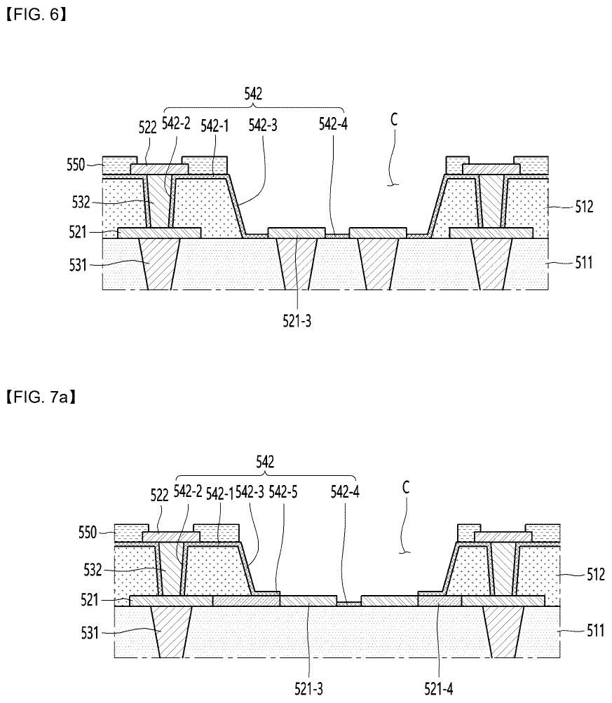

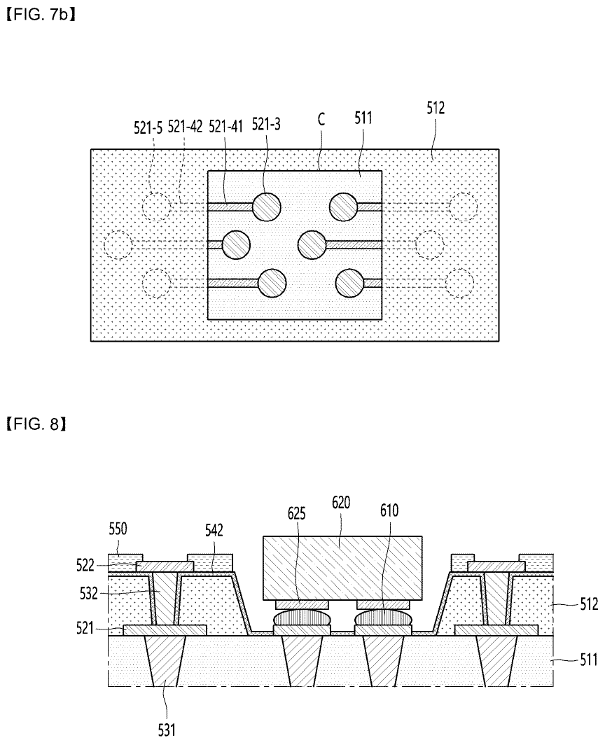

FIG. 7a is a cross-sectional view showing a circuit board according to a third embodiment and FIG. 7b is a plan view of the circuit board of FIG. 7a.

Referring to FIGS. 7a and 7b, the circuit board of the third embodiment has a structure similar to that of the second embodiment, and may be different in that a fourth pattern 542-4 is disposed on the first insulating layer 511.

At this time, the second insulating layer 512 of the embodiment includes a photocurable resin. Accordingly, the embodiment can perform an exposure and development process instead of a laser process when forming a cavity C in the second insulating layer 512.

Here, the first insulating layer 511 includes a thermosetting resin. Accordingly, when a development process for forming a cavity C in the second insulating layer 512 is performed, the first insulating layer 511 may not be removed. Therefore, the embodiment can form a cavity C penetrating only the second insulating layer 512 without a stopper for forming the cavity C.

Therefore, the embodiment can provide a fourth pattern 521-4 of the first circuit pattern layer 521 that is directly connected to the third pattern 521-3 of the first circuit pattern layer 521 in a region vertically overlapping the cavity C.

That is, since a conventional structure has a stopper for forming the cavity C, the third pattern vertically overlapping the cavity and the fifth pattern not vertically overlapping the cavity among the first circuit pattern layers cannot be directly connected to each other. Accordingly, conventionally, the third pattern and the fifth pattern of the first circuit pattern layer are connected to each other using a through electrode penetrating the first insulating layer 511.

Unlike this, the second insulating layer 512 of the embodiment includes a photocurable resin, and thus, the stopper required to form the cavity C can be removed.

Therefore, the embodiment can dispose the fourth pattern 521-4 on the first insulating layer 511 that vertically overlaps the cavity C. The fourth pattern 521-4 may be a trace that directly connects the third pattern 521-3 that vertically overlaps the cavity C and the fifth pattern 521-5 that does not vertically overlap the cavity C. At this time, the fifth pattern 521-5 of the first circuit pattern layer 521 may mean the first pattern 421-1 or/and the second pattern 421-2 of the first circuit pattern layer 421 included in the circuit board of the first embodiment.

Accordingly, the fourth pattern 521-4 of the first circuit pattern layer 521 of the embodiment may be divided into a plurality of parts. The fourth pattern 521-4 of the first circuit pattern layer 521 may include a first part 521-41 that is directly connected to the third pattern 521-3 and vertically overlaps with the cavity C. In addition, the fourth pattern 521-4 of the first circuit pattern layer 521 may include a second part 521-42 that extends from the first part 521-41 and does not vertically overlap the cavity C.

That is, the first part 521-41 of the fourth pattern 521-4 of the first circuit pattern layer 521 may refer to a portion that is directly connected to the third pattern 521-3 while being exposed through the cavity C. In addition, the second part 521-42 of the fourth pattern 521-4 of the first circuit pattern layer 521 may refer to a portion that is covered with the second insulating layer 512 and connects the first part 521-41 of the fourth pattern 521-4 and the fifth pattern 521-5.

Accordingly, the embodiment can directly connect the third pattern 521-3 and the fifth pattern 521-5 by using the fourth pattern 521-4. Accordingly, the embodiment can minimize a signal transmission distance of the semiconductor device or the external substrate disposed on the third pattern 521-3, thereby minimizing signal transmission loss.

Meanwhile, the second buffer layer 542 can further include a fifth portion 542-5. The fifth portion 542-5 of the second buffer layer 542 can be disposed to cover a side surface and an upper surface of the first part 521-41 of the fourth pattern 521-4 exposed through the cavity C. Accordingly, the embodiment can stably protect the fourth pattern 521-4 exposed through the cavity C. In addition, the embodiment can improve the adhesion with the molding layer when forming a molding layer that fills the cavity C.

FIG. 8 is a drawing showing a semiconductor package of a seventh embodiment, and FIG. 9 is a drawing showing a semiconductor package of an eighth embodiment.

Referring to FIG. 8, the semiconductor package of a seventh embodiment includes a connection member 610 disposed on the third pattern 521-3 of the first circuit pattern layer 521 exposed through the cavity C.

In addition, the semiconductor package of the seventh embodiment includes a semiconductor device 620 disposed on the connection member 610. The semiconductor device 620 includes a terminal 625, and the terminal 625 can be electrically connected to the third pattern 521-3 of the first circuit pattern layer 521 through the connection member 610.

In addition, referring to FIG. 9, the semiconductor package of the eighth embodiment can further include a molding layer 630 filling the cavity C. In addition, the molding layer 630 can be in contact with the second buffer layer 542.

Hereinafter, a method for manufacturing a circuit board according to an embodiment will be described in process order.

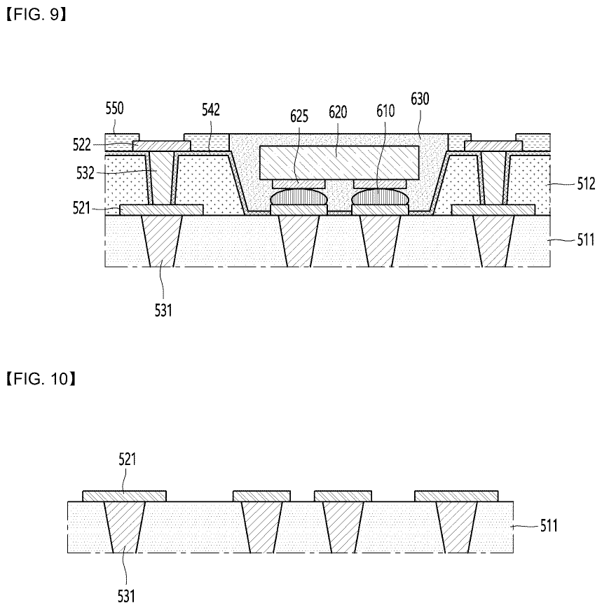

FIGS. 10 to 17 are cross-sectional views for explaining a method of manufacturing a circuit board of the embodiment in order of processes. Hereinafter, a method for manufacturing a circuit board including a cavity will be described. However, for convenience of explanation, a description will be made focusing on layers sequentially disposed above the first insulating layer 511 based on the first insulating layer 511.

Referring to FIG. 10, the embodiment prepares the first insulating layer 511. Thereafter, the embodiment forms a through hole penetrating the first insulating layer 511. Thereafter, the embodiment performs a process of forming a through electrode 531 filling the through hole of the first insulating layer 511 and a first circuit pattern layer 521 disposed on the upper surface of the first insulating layer 511.

Next, referring to FIG. 11, the embodiment can perform a process of forming a first buffer layer 541. At this time, the first buffer layer 541 may be formed entirely on an exposed surface of the first insulating layer 511 and an exposed surface of the first circuit pattern layer 521. Thereafter, the embodiment may perform a process of removing a region of an entire region of the first buffer layer 541 that vertically overlaps with the through electrode penetrating the second insulating layer. However, the removing process may be performed after a through hole is formed in the second insulating layer 512. Hereinafter, the removing process will be described as being performed after a through hole is formed in the second insulating layer 512.

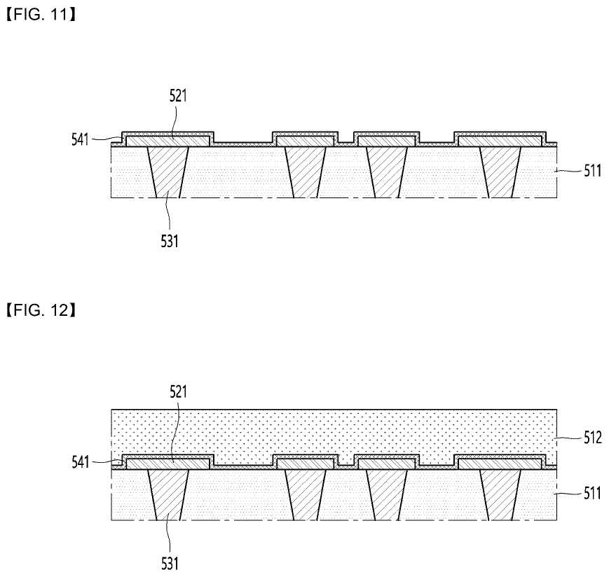

Thereafter, referring to FIG. 12, the embodiment may perform a process of stacking the second insulating layer 512 on the first buffer layer 541. The second insulating layer 512 may include a photocurable resin.

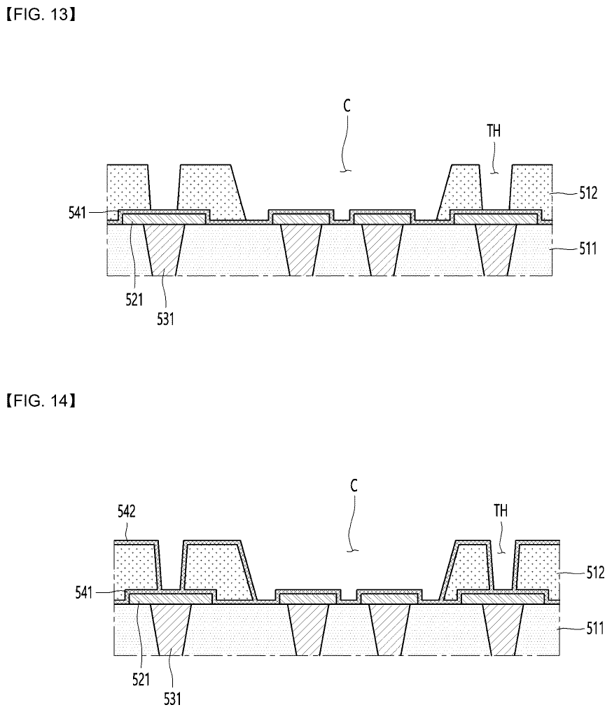

Next, referring to FIG. 13, the embodiment may perform a process of processing the second insulating layer 512. Specifically, the processing process may refer to a process of exposing and developing the second insulating layer 512.

For example, the embodiment may remove a region where a through hole TH is to be formed in the second insulating layer 512 by exposing and developing. In addition, the embodiment may remove a region where a cavity C is to be formed in the second insulating layer 512 by exposing and developing. At this time, the process of forming the through hole TH and the process of forming the cavity C may be performed simultaneously, but are not limited thereto.

Next, referring to FIG. 14, the embodiment may perform a process of forming a second buffer layer 542 on the second insulating layer 512. At this time, the second buffer layer 542 may be disposed on the upper surface of the second insulating layer 512, the inner wall of the through hole TH, and the inner wall of the cavity C, respectively. In addition, at least a part of the second buffer layer 542 may be connected to the first buffer layer 541.

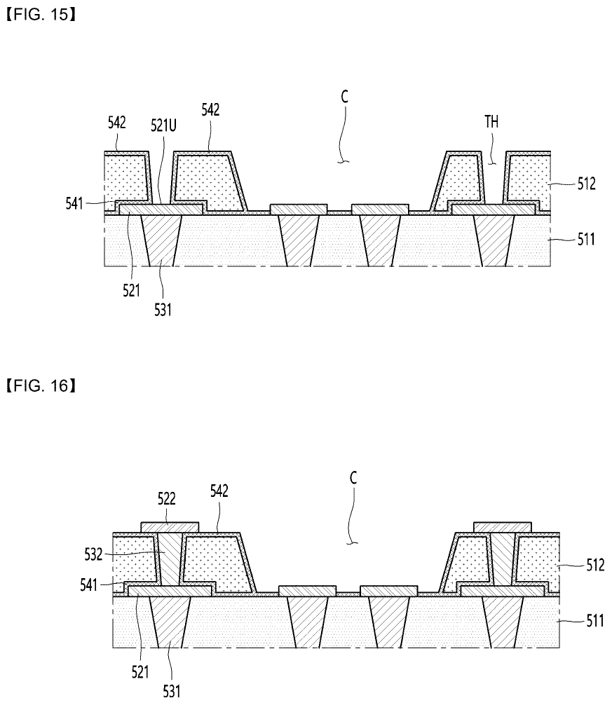

Thereafter, referring to FIG. 15, the embodiment may perform a process of removing a region vertically overlapping the through hole TH among the entire region of the first buffer layer 541. In other words, the embodiment may perform a process of removing the first buffer layer 541 to expose an upper surface 521U of the first circuit pattern layer 521 vertically overlapping the through hole TH among the first circuit pattern layer 521. The process of removing the first buffer layer 541 may be performed using a wet method, or alternatively, may be performed using a dry method. When using a wet method, a part of the first buffer layer 541 may be selectively removed using a hydrofluoric acid chemical. In addition, when using a dry method, a part of the first buffer layer 541 may be selectively removed using a laser.

In addition, the embodiment may perform a process of removing a region adjacent to the third pattern 521-3 of the first circuit pattern layer 521 exposed through the cavity C among the first buffer layer 541 or the second buffer layer 542. For example, the embodiment may remove at least a portion of the first buffer layer 541 and the second buffer layer 542, thereby exposing at least a portion of the side surface and the upper surface of the third pattern 521-3 vertically overlapping the cavity C.

Next, referring to FIG. 16, the embodiment may perform a process of forming a through electrode 532 filling the through hole TH of the second insulating layer 512 and a second circuit pattern layer 522 disposed on the second insulating layer 512.

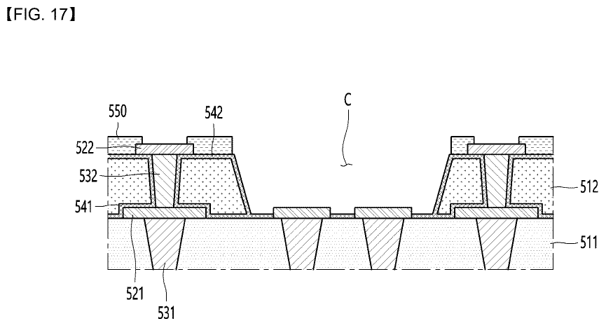

Thereafter, referring to FIG. 17, the embodiment may proceed with a process of forming a first protective layer 550 on the second buffer layer 542. The first protective layer 550 may include an opening vertically overlapping the cavity C. In addition, the first protective layer 550 may proceed with a process of removing at least a portion of the upper surface of the second circuit pattern layer 522.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

Features, structures, effects, etc. described in the above embodiments are included in at least one embodiment, and it is not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and variations should be interpreted as being included in the scope of the embodiments.

In the above, the embodiment has been mainly described, but this is only an example and does not limit the embodiment, and those of ordinary skill in the art to which the embodiment pertains will appreciate that various modifications and applications not illustrated above are possible without departing from the essential characteristics of the present embodiment. For example, each component specifically shown in the embodiment can be implemented by modification. In addition, the differences related to these modifications and applications should be interpreted as being included in the scope of the embodiments set forth in the appended claims.

1-10. (canceled)

11. A circuit board comprising:
a first insulating layer;
a circuit pattern layer disposed on the first insulating layer;
an oxide layer disposed on the circuit pattern layer; and
a second insulating layer disposed on the oxide layer,
wherein the first insulating layer includes thermosetting insulating material,
wherein the second insulating layer includes a photosensitive insulating material, and
wherein a thickness of the oxide layer in a vertical direction is smaller than a thickness of the circuit pattern layer in the vertical direction.

12. The circuit board of claim 11, wherein the oxide layer includes a first portion disposed between the circuit pattern layer and the second insulating layer, and a second portion connected to the first portion and disposed between the first insulating layer and the second insulating layer.

13. The circuit board of claim 11, further comprising:
a through electrode penetrating at least a portion of the second insulating layer along the vertical direction and connected to the circuit pattern layer.

14. The circuit board of claim 13, wherein the oxide layer includes an open region overlapping a lower surface of the through electrode along the vertical direction, and
wherein the through electrode is disposed in the open region and in direct contact with the circuit pattern layer.

15. The circuit board of claim 11, wherein the first insulating layer includes a reinforcing fiber.

16. The circuit board of claim 13, further comprising:
an upper oxide layer disposed on the second insulating layer, and
a protective layer disposed on the upper oxide layer.

17. The circuit board of claim 16, further comprising:
an upper circuit pattern layer disposed between the second insulating layer and the protective layer,
wherein the upper oxide layer includes a first portion disposed between the upper circuit pattern layer and the protective layer, and a second portion connected to the first portion and disposed between the second insulating layer and the protective layer.

18. The circuit board of claim 17, wherein a thickness of the upper oxide layer in the vertical direction is smaller than a thickness of the upper circuit pattern layer in the vertical direction.

19. The circuit board of claim 17, wherein the protective layer includes an opening overlapping the circuit pattern layer along the vertical direction, and
wherein the upper oxide layer includes an open region overlapping the opening of the protective layer along the vertical direction.

20. The circuit board of claim 17, wherein the upper oxide layer further includes a third portion extending from the first portion toward the first insulating layer and positioned between an inner wall of a through hole of the second insulating layer and the through electrode.

21. The circuit board of claim 17, wherein the second insulating layer includes a cavity, and
wherein the upper oxide layer further includes a portion disposed on an inner wall of the cavity.

22. The circuit board of claim 21, wherein the cavity penetrates upper and lower surfaces of the second insulating layer, and
wherein the upper oxide layer further includes a portion disposed on an upper surface of the first insulating layer corresponding to a lower surface of the cavity.

23. The circuit board of claim 21, wherein the circuit pattern layer further includes a pad layer overlapping the cavity along the vertical direction, and
wherein the oxide layer and the upper oxide layer do not overlap with the pad layer along the vertical direction.

24. The circuit board of claim 23, wherein the circuit pattern layer further includes a wiring layer overlapped along the horizontal direction with the pad layer and not overlapped with the cavity along the vertical direction, and a connection wiring directly connecting the wiring layer and the pad layer.

25. The circuit board of claim 24, wherein the connection wiring includes an overlapping portion overlapping the cavity along the vertical direction, and
wherein at least one of the oxide layer and the upper oxide layer is disposed to cover the overlapping portion.

26. The circuit board of claim 23, further comprising:
a semiconductor device disposed on the pad layer and disposed in the cavity.

27. The circuit board of claim 26, further comprising:
a burying insulating layer disposed in the cavity and embedding the semiconductor device.

28. The circuit board of claim 27, wherein the burying insulating layer is in contact with the upper oxide layer.
